(19) United States
(12) Patent Application Publication
(10) Pub. No.: US 2026/0353566 A1
(43) Pub. Date: Nov. 5, 2026

(54) CIRCUIT BOARD AND SEMICONDUCTOR PACKAGE COMPRISING SAME

(71) Applicant: LG INNOTEK CO., LTD., Seoul (KR)

(72) Inventors: Jong Bae SHIN, Seoul (KR); Woo Seop SIM, Seoul (KR); Jae Hun JEONG, Seoul (KR); Ji Chul JUNG, Seoul (KR)

(73) Assignee: LG INNOTEK CO., LTD., Seoul (KR)

(21) Appl. No.: 19/101,978

(22) PCT Filed: Aug. 10, 2023
(86) PCT No.: PCT/KR2023/011824

§ 371 Date: Feb. 7, 2025

(30) Foreign Application Priority Data
Aug. 10, 2022 (KR) 10-2022-0100205

(51) Int. Cl. H05K 1/183; H05K 1/11

(52) U.S. Cl. CPC H05K 1/183; H05K 1/111; H05K 2201/09036; H05K 2201/09845; H05K 2201/09863; H05K 2201/10515; H05K 2201/10522; H05K 2201/10734

(57) ABSTRACT

A circuit board according to an embodiment includes a first insulating layer; a second insulating layer disposed on the first insulating layer; and a circuit pattern layer disposed between the first and second insulating layers, wherein the second insulating layer has a cavity passing through upper and lower surfaces, and the circuit pattern layer includes an electrode pattern extending from an inner side of the cavity to an outer side of the cavity.

### TECHNICAL FIELD

An embodiment relates to a circuit board and a semiconductor package including the same.

### BACKGROUND ART

As performances of electric/electronic products progresses, technologies for disposing a greater number of packages on a circuit board of a limited size are being proposed and studied.

A typical semiconductor package has a structure in which multiple chips are disposed. In addition, recently, products to which the semiconductor package is applied are becoming more high-spec, and multiple chips such as HBM (High Bandwidth Memory) are being adopted, and as a result, a size of the semiconductor package is increasing. Accordingly, the semiconductor package includes an interposer to connect multiple chips.

In addition, semiconductor packages applied to products providing the Internet of Things (IoT), autonomous vehicles, and high-performance servers require high performance and high reliability in accordance with a trend of high integration.

Furthermore, the semiconductor package has a vertical connection structure between multiple substrates, interposers, and semiconductor devices. Accordingly, a thickness of the semiconductor package in a vertical direction can increase depending on a thickness and a number of the circuit board, the interposer, and the semiconductor device.

Therefore, the semiconductor package reduces the thickness in the vertical direction by using a circuit board having a cavity. The cavity can be formed by processing the circuit board with a laser. For this purpose, a dummy pattern is provided in the circuit board. In addition, the dummy pattern is used as a stopper to perform a laser process to form the cavity.

According to a conventional technology, a process of forming the dummy pattern and a process of removing the dummy pattern must be performed, and there is a problem that a manufacturing process becomes complicated.

In addition, the circuit board of the conventional technology includes a pad exposed through the cavity. At this time, only the pad exists in a region exposed through the cavity. This is because, when an electrode pattern such as a trace exists in the region exposed through the cavity, a circuit short problem occurs in which the traces are electrically connected to each other by the dummy pattern. Therefore, the circuit board of the conventional technology has a problem in that the circuit integration is reduced.
(Patent Document 1) KR 10-2012-0045639 A

### DISCLOSURE

### Technical Problem

The embodiment provides a circuit board having a novel structure and a semiconductor package including the same.

In addition, the embodiment provides a circuit board capable of being slimmed down and a semiconductor package including the same.

In addition, the embodiment provides a circuit board capable of minimizing a length of a signal line connected to a connection member and a semiconductor package including the same.

In addition, the embodiment provides a circuit board capable of arranging an electrode pattern in a cavity region while including a thermosetting resin and a semiconductor package including the same.

In addition, the embodiment provides a circuit board having an improved circuit integration and a semiconductor package including the same.

In addition, the embodiment provides a circuit board having an improved adhesion with a molding member and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises a first insulating layer; a second insulating layer disposed on the first insulating layer; and a circuit pattern layer disposed between the first and second insulating layers, wherein the second insulating layer has a cavity passing through upper and lower surfaces, and wherein the circuit pattern layer includes an electrode pattern extending from an inner side of the cavity to an outer side of the cavity.

In addition, the circuit pattern layer further includes: a first pad disposed on the inner side of the cavity overlapped in a vertical direction with the cavity; and a second pad disposed on the outer side of the cavity that does not vertically overlap with the cavity.

In addition, the second insulating layer has a concave portion recessed in a direction from a lower end of a sidewall of the cavity toward the outer side of the cavity.

In addition, the concave portion has a first portion that does not overlap with the electrode pattern in a vertical direction, and a second portion that overlaps with the electrode pattern in the vertical direction.

In addition, the circuit pattern layer is provided to protrude on the first insulating layer, and the first portion of the concave portion is provided along an edge of the lower end of the side wall of the cavity.

In addition, the first and second portions of the concave portion have a step.

In addition, each of the first pad, the second pad, and the electrode pattern includes: a first metal layer disposed on the first insulating layer; and a second metal layer disposed on the first metal layer, and wherein a length of the first portion of the concave portion in the vertical direction corresponds to a thickness of the first metal layer.

In addition, a horizontal distance from the lower end of the side wall of the cavity to an innermost end of the first portion of the concave portion satisfies a range of 5 μm to 17 μm.

In addition, a horizontal length of the first portion of the concave portion is different from a horizontal length of the second portion of the concave portion.

In addition, a thickness of the first pad is different from a thickness of the second pad.

In addition, the length of the first portion of the concave portion in the vertical direction satisfies a range of 1.0 μm to 4.0 μm.

In addition, a horizontal length of the first portion of the concave portion is smaller than a horizontal length of the second portion of the concave portion.

In addition, a thickness of the first pad is smaller than a thickness of the second pad.

In addition, the electrode pattern includes a region that overlaps the side wall of the cavity in a vertical direction and changes in thickness along the horizontal direction.

In addition, the first pad, the second pad, and the electrode pattern are embedded in the upper surface of the first insulating layer, and an upper surface of the first region of the first insulating layer is positioned lower than an upper surface of the second region of the first insulating layer.

In addition, the concave portion is provided concavely from the upper surface of the first region of the first insulating layer toward an inner side of the first insulating layer.

In addition, at least one of the first pad, the second pad, and the electrode pattern has a layer structure different from at least one other.

In addition, the first circuit pattern layer includes a first metal layer and a second metal layer, the first pad of the first circuit pattern layer includes a second metal layer excluding the first metal layer, the second pad of the first circuit pattern layer includes both the first metal layer and the second metal layer, and the electrode pattern includes a first portion including only the second metal layer and a second portion including both the first and second metal layers.

In addition, the second insulating layer having the cavity includes a thermosetting resin.

### Advantageous Effects

The circuit board of the embodiment comprises a first insulating layer, a first circuit pattern layer disposed on the first insulating layer; and a second insulating layer disposed on the first insulating layer and the first circuit pattern layer. At this time, the second insulating layer includes a cavity passing through an upper surface and a lower surface. In addition, the first circuit pattern layer may include a first pad disposed in a first region vertically overlapping the cavity; a second pad disposed in a second region not vertically overlapping the cavity; and an electrode pattern disposed in the first region and the second region and connecting the first pad and the second pad.

That is, the embodiment arranges an electrode pattern directly connecting the first pad and the second pad on the first insulating layer. Accordingly, the embodiment can reduce a signal transmission distance between the first pad and the second pad. Furthermore, the embodiment can minimize call transmission loss by reducing the signal transmission distance. Accordingly, the embodiment can improve electrical characteristics of the circuit board and the semiconductor package including the same.

In addition, the embodiment can improve the circuit integration by arranging the electrode pattern in a region corresponding to the cavity.

Meanwhile, the second insulating layer including the cavity includes a thermosetting resin. In addition, the embodiment can arrange the electrode pattern while the second insulating layer includes a thermosetting resin. The embodiment can improve the adhesion between a plurality of insulating layers by forming the insulating layer using a thermosetting resin. Accordingly, the embodiment can improve physical characteristics of the circuit board and the semiconductor package including the same.

Meanwhile, a concave portion can be provided along a circumferential direction of a lower surface of the cavity at a lower end of the side wall of the cavity. The concave portion can have a closed loop shape along the circumferential direction of the lower surface of the cavity. At this time, the concave portion may include a portion having a step in one embodiment, and may not have a step in another embodiment.

Therefore, the embodiment arranges a connection member and a molding member for molding the connection member in the cavity. In addition, the molding member can fill the concave portion provided in the cavity. At this time, the embodiment may allow a portion of an entire region of the molding member positioned in the concave portion to function as an anchor. Therefore, the embodiment can improve the adhesion between the circuit board and the molding member. Accordingly, the embodiment can protect the connection member more stably. In addition, the embodiment can further improve product reliability of the semiconductor package.

### DESCRIPTION OF DRAWINGS

FIG. 1a is a cross-sectional view showing a semiconductor package according to a first embodiment.

FIG. 1b is a cross-sectional view showing a semiconductor package according to a second embodiment.

FIG. 1c is a cross-sectional view showing a semiconductor package according to a third embodiment.

FIG. 1d is a cross-sectional view showing a semiconductor package according to a fourth embodiment.

FIG. 1e is a cross-sectional view showing a semiconductor package according to a fifth embodiment.

FIG. 1f is a cross-sectional view showing a semiconductor package according to a sixth embodiment.

FIG. 1g is a cross-sectional view showing a semiconductor package according to a seventh embodiment.

FIG. 2 is a cross-sectional view showing a circuit board according to a first embodiment.

FIG. 3 is a plan view showing a first insulating layer and a first circuit pattern layer in the circuit board of FIG. 2.

FIG. 4 is a plan view showing a circuit board of FIG. 3 with some configurations removed.

FIG. 5 is a cross-sectional view taken along a A-A′ direction of FIGS. 3 and 4.

FIG. 6 is an optical microscope photograph of an actual product corresponding to FIG. 5.

FIG. 7 is a cross-sectional view taken along a B-B′ direction of FIGS. 3 and 4.

FIG. 8 is a cross-sectional view showing a circuit board according to a second embodiment.

FIG. 9 is an enlarged view showing a partial region of the cavity of FIG. 8.

FIG. 10 is an enlarged view showing another partial region of the cavity of FIG. 8.

FIG. 11 is a drawing showing a package substrate according to an embodiment.

FIGS. 12 to 22 are drawings showing a method for manufacturing a circuit board of FIG. 2 according to an embodiment in order of processes.

### BEST MODE

Hereinafter, exemplary embodiments of the present invention will be described in detail with reference to the accompanying drawings, wherein like reference numerals are used to designate identical or similar elements, and redundant description thereof will be omitted. The suffix “module” and “portion” of the components used in the following description are only given or mixed in consideration of ease of preparation of the description, and there is no meaning or role to be distinguished as it is from one another. Also, in the following description of the embodiments of the present invention, a detailed description of related arts will be omitted when it is determined that the gist of the embodiments disclosed herein may be obscured. Also, the accompanying drawings are included to provide a further understanding of the invention, are incorporated in, and constitute a part of this description, and it should be understood that the invention is intended to cover all modifications, equivalents, or alternatives falling within the spirit and scope of the invention.

Terms including ordinals, such as first, second, etc., may be used to describe various components, but the elements are not limited to these terms. The terms are used only for distinguishing one component from another.

When a component is referred to as being “connected” or “contacted” to another component, it may be directly connected or joined to the other component, but it should be understood that other component may be present therebetween. When a component is referred to as being “directly connected” or “directly contacted” to another component, it should be understood that other component may not be present therebetween.

A singular representation includes plural representations, unless the context clearly implies otherwise.

In the present application, terms such as “including” or “having” are used to specify the presence of features, numbers, steps, operations, components, parts, or combinations thereof described in the description. However, it should be understood that the terms do not preclude the presence or addition of one or more other features, numbers, steps, operations, components, parts, or combinations thereof.

Hereinafter, embodiments of a present invention will be described in detail with reference to attached drawings.

### Electronic Device

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package.

The semiconductor device may include an active device and/or a passive device. The active device may be a semiconductor chip in the form of an integrated circuit (IC) in which hundreds to millions of devices are integrated in one semiconductor device. The semiconductor device may be a logic chip, a memory chip, or the like. The logic chip may be a central processor (CPU), a graphics processor (GPU), or the like. For example, the logic chip may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far.

The memory chip may be a stack memory such as HBM. The memory chip may also include a memory chip such as volatile memory (e.g., DRAM), non-volatile memory (e.g., ROM), flash memory, and the like.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In addition, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

Hereinafter, a semiconductor package including a circuit board according to an embodiment will be described. The semiconductor package of the embodiment may have various package structures including a circuit board to be described later.

In addition, the circuit board in one embodiment may be a first circuit board described below.

In addition, the circuit board in another embodiment may be a second circuit board described below.

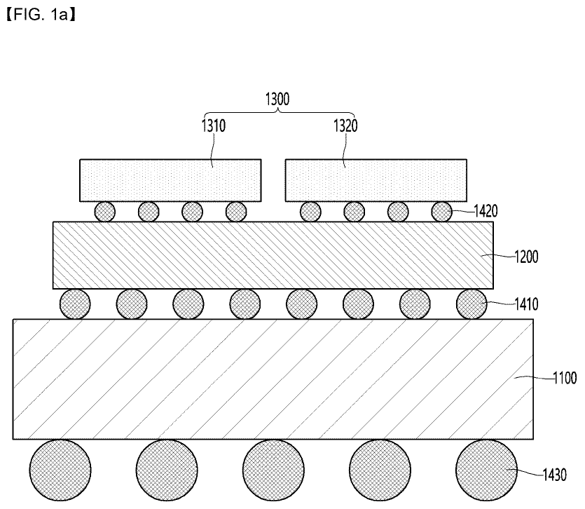

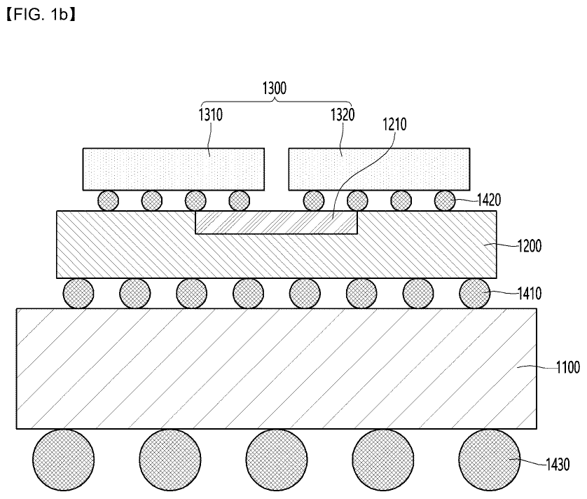

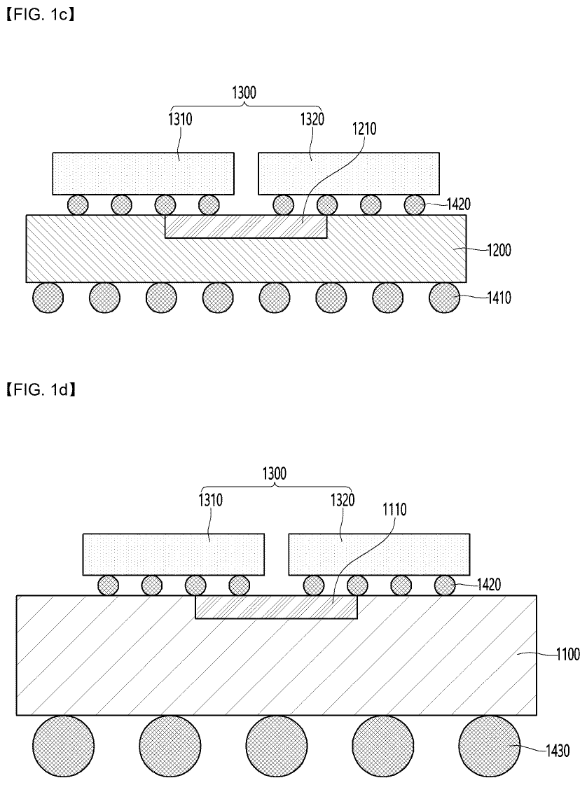

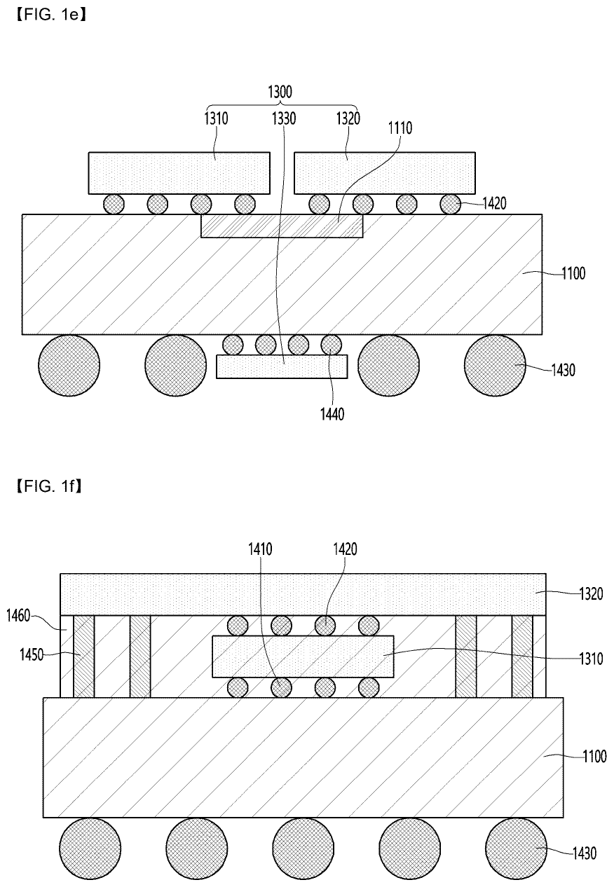

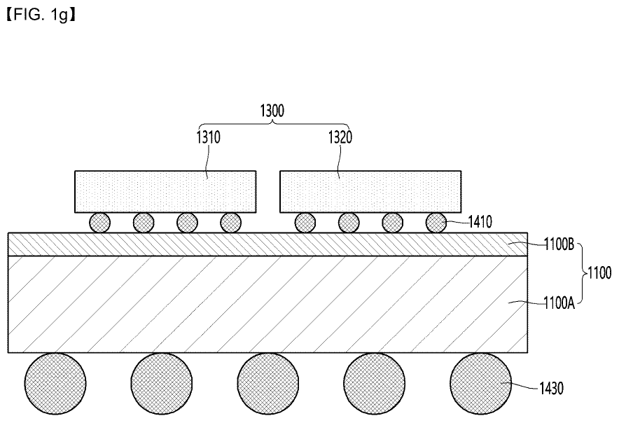

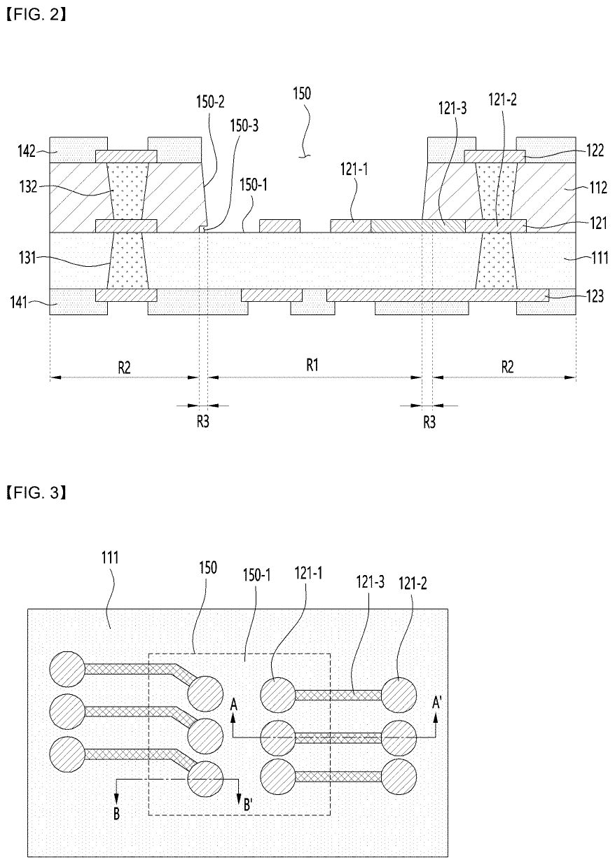

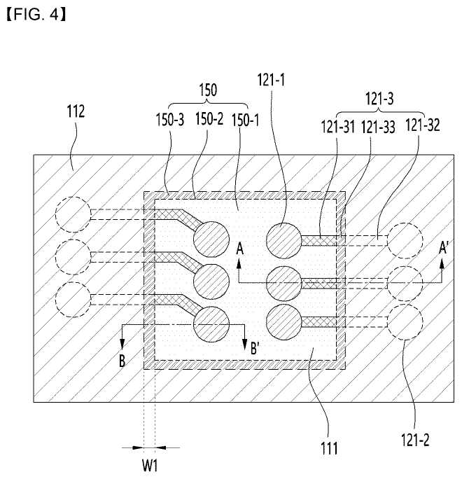

FIG. 1a is a cross-sectional view showing a semiconductor package according to a first embodiment, FIG. 1b is a cross-sectional view showing a semiconductor package according to a second embodiment, FIG. 1c is a cross-sectional view showing a semiconductor package according to a third embodiment, FIG. 1d is a cross-sectional view showing a semiconductor package according to a fourth embodiment, FIG. 1e is a cross-sectional view showing a semiconductor package according to a fifth embodiment, FIG. 1f is a cross-sectional view showing a semiconductor package according to a sixth embodiment, and FIG. 1g is a cross-sectional view showing a semiconductor package according to a seventh embodiment.

Referring to FIG. 1a, the semiconductor package according to the first embodiment includes a first circuit board 1100, a second circuit board 1200, and a semiconductor device 1300.

The first circuit board 1100 means a package substrate.

For example, the first circuit board 1100 may provide a space to which at least one external circuit board is coupled. The external circuit board may refer to a second circuit board 1200 coupled to the first circuit board 1100. Also, the external circuit board may refer to a main board included in an electronic device coupled to a lower portion of the first circuit board 1100.

Also, although not shown in the drawing, the first circuit board 1100 may provide a space in which at least one semiconductor device is mounted. To this end, the first circuit board 1100 may include a cavity. In addition, at least one semiconductor device may be disposed in the cavity of the first circuit board 1100.

The first circuit board 1100 includes at least one insulating layer, an electrode disposed on the at least one insulating layer, and a through part passing through the at least one insulating layer.

A second circuit board 1200 is disposed on the first circuit board 1100.

The second circuit board 1200 may be an interposer. For example, the second circuit board 1200 may provide a space in which at least one semiconductor device is mounted. The second circuit board 1200 may be connected to the at least one semiconductor device 1300. For example, the second circuit board 1200 may provide a space in which the first semiconductor device 1310 and the second semiconductor device 1320 are mounted. The second circuit board 1200 may electrically connect the first and second semiconductor devices 1310 and 1320 and the first circuit board 1100 while electrically connecting the first semiconductor device 1310 and the second semiconductor device 1320. That is, the second circuit board 1200 may perform a horizontal connection function between a plurality of semiconductor devices and a vertical connection function between the semiconductor devices and the package substrate.

FIG. 1a illustrates that the first and second semiconductor devices 1310 and 1320 are disposed on the second circuit board 1200, but is not limited thereto. For example, one semiconductor device may be disposed on the second circuit board 1200, or alternatively, three or more semiconductor devices may be disposed.

The second circuit board 1200 may be disposed between at least one semiconductor device 1300 and the first circuit board 1100.

In one embodiment, the second circuit board 1200 may be an active interposer that functions as a semiconductor device. When the second circuit board 1200 functions as a semiconductor device, a package of the embodiment may have a vertically stacked structure on the first circuit board 1100 and may have a plurality of logic chips mounted thereon. In addition, among the logic chips, a first logic chip corresponding to the active interposer may perform a function of a corresponding logic chip while performing a signal transmission function between the second logic chip disposed thereon and the first circuit board 1100.

According to another embodiment, the second circuit board 1200 may be a passive interposer. For example, the second circuit board 1200 may function as a signal relay between the semiconductor device 1300 and the first circuit board 1100. That is, a number of terminals of the semiconductor device 1300 is gradually increasing due to 5G, Internet of Things (IOT), increased image quality, and increased communication speed. That is, the number of terminals provided in the semiconductor device 1300 increases, thereby reducing the width of the terminals or an interval between the plurality of terminals. In this case, the first circuit board 1100 is connected to the main board of the electronic device. There is a problem in that the thickness of the first circuit board 1100 increases or the layer structure of the first circuit board 1100 becomes complicated in order for the electrodes provided on the first circuit board 1100 to have a width and an interval to be respectively connected to the semiconductor device 1300 and the main board. Accordingly, in the first embodiment, the second circuit board 1200 is disposed on the first circuit board 1100 and the semiconductor device 1300. In addition, the second circuit board 1200 may include electrodes having a fine width and a spacing corresponding to the terminals of the semiconductor device 1300.

The semiconductor device 1300 may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far. The memory chip may be a stack memory such as HBM. The memory chip may also include a memory chip such as volatile memory (e.g., DRAM), non-volatile memory (e.g., ROM), flash memory, and the like.

Meanwhile, the second circuit board 1200 may include at least one cavity. In addition, the semiconductor device 1300 may be disposed in the cavity of the second circuit board 1200.

Meanwhile, the semiconductor package of the first embodiment may include a connection member.

For example, the semiconductor package includes a first connection member 1410 disposed between the first circuit board 1100 and the second circuit board 1200. The first connection member 1410 may electrically connect the second circuit board 1200 to the first circuit board 1100 while coupling them.

For example, the semiconductor package includes a second connection member 1420 disposed between the second circuit board 1200 and the semiconductor device 1300. The second connection member 1420 may electrically connect the semiconductor device 1300 to the second circuit board 1200 while coupling them.

The semiconductor package includes a third connection member 1430 disposed on a lower surface of the first circuit board 1100. The third connection member 1430 may electrically connect the first circuit board 1100 to the main board while coupling them.

At this time, the first connection member 1410, the second connection member 1420, and the third connection member 1430 may electrically connect between the plurality of components by using at least one bonding method of wire bonding, solder bonding and metal-to-metal direct bonding. That is, since the first connection member 1410, the second connection member 1420, and the third connection member 1430 have a function of electrically connecting a plurality of components, when the metal-to-metal direct bonding is used, the connection member of the semiconductor package may be understood as an electrically connected portion, not a solder or wire.

The wire bonding method may refer to electrically connecting a plurality of components using a conductive wire such as gold (Au). Also, the solder bonding method may electrically connect a plurality of components using a material containing at least one of Sn, Ag, and Cu. In addition, the metal-to-metal direct bonding method may refer to recrystallization by applying heat and pressure between a plurality of components without the presence of solder, wire, conductive adhesive, etc. In addition, to directly bond between the plurality of components. In addition, the metal-to-metal direct bonding method may refer to a bonding method by the second connection member 1420. In this case, the second connection member 1420 may mean a metal layer formed between a plurality of components by the recrystallization.

Specifically, the first connection member 1410, the second connection member 1420, and the third connection member 1430 may couple a plurality of components to each other by a thermal compression (TC) bonding method. The thermal compression bonding may refer to a method of directly coupling a plurality of components by applying heat and pressure to the first connection member 1410, the second connection member 1420, and the third connection member 1430.

At this time, at least one of the first circuit board 1100 and the second circuit board 1200 may have a protrusion disposed on an electrode where the first connection member 1410, the second connection member 1420, and the third connection member 1430 are disposed. The protrusion may protrude outwardly from the first circuit board 1100 or the second circuit board 1200.

The protrusion may mean a bump. The protrusion may mean a post. The protrusion may mean a pillar. Preferably, the protrusion may refer to an electrode on which a second connection member 1420 for coupling with the semiconductor device 1300 is disposed among the electrodes of the second circuit board 1200. That is, as the pitch of the terminals of the semiconductor device 1300 becomes finer, a short circuit may occur between the plurality of second connection members 1420 that are respectively connected to the plurality of terminals of the semiconductor device 1300. Accordingly, the embodiment allows a protrusion to be included in an electrode of the second circuit board 1200 on which the second connection member 1420 is disposed in order to reduce a volume of the second connection member 1420. The protrusion can improve the alignment between the electrode of the second substrate 1200 and the terminal of the semiconductor device 1300 and prevent diffusion of the second connection member 1420.

Meanwhile, referring to FIG. 1b, the semiconductor package of the second embodiment may differ from the semiconductor package of the first embodiment in that the connection substrate 1210 is disposed on the second circuit board 1200. The connection substrate 1210 may be referred to as a bridge substrate. For example, the connection substrate 1210 may include a redistribution layer.

In an embodiment, the connection substrate 1210 may be a silicon bridge. That is, the connection substrate 1210 may include a silicon substrate and a redistribution layer disposed on the silicon substrate.

In another embodiment, the connection substrate 1210 may be an organic bridge. For example, the connection substrate 1210 may include an organic material. For example, the connection substrate 1210 includes an organic substrate including an organic material instead of the silicon substrate.

The connection substrate 1210 may be embedded in the second circuit board 1200, but is not limited thereto. For example, the connection substrate 1210 may be disposed on the second circuit board 1200 to have a protruding structure.

Preferably, the second circuit board 1200 may include a cavity, and the connection substrate 1210 may be disposed in the cavity of the second circuit board 1200.

The connection substrate 1210 may horizontally connect a plurality of semiconductor devices disposed on the second circuit board 1200.

Referring to FIG. 1c, the semiconductor package according to the third embodiment includes a second circuit board 1200 and a semiconductor device 1300. In this case, the semiconductor package of the third embodiment may have a structure in which the first circuit board 1100 is removed compared to the semiconductor package of the second embodiment.

That is, the second circuit board 1200 of the third embodiment may function as a package substrate while performing an interposer function.

The first connection member 1410 disposed on the lower surface of the second circuit board 1200 may couple the second circuit board 1200 to the main board of the electronic device.

Referring to FIG. 1d, the semiconductor package according to the fourth embodiment includes a first circuit board 1100 and a semiconductor device 1300.

In this case, the semiconductor package of the fourth embodiment may have a structure in which the second circuit board 1200 is removed compared to the semiconductor package of the second embodiment.

That is, the first circuit board 1100 of the fourth embodiment can function as a package substrate while also performing an interposer function of connecting the semiconductor device 1300 and a main board. To this end, the first circuit board 1100 may include a connection member 1110 for connecting the plurality of semiconductor devices. The connection member 1110 may be a silicon bridge or an organic material bridge connecting a plurality of semiconductor devices.

Referring to FIG. 1e, the semiconductor package of the fifth embodiment further includes a third semiconductor device 1330 compared to the semiconductor package of the fourth embodiment.

To this end, a fourth connection member 1440 may be disposed on the lower surface of the first circuit board 1100.

In addition, a third semiconductor device 1330 may be disposed on the fourth connection member 1400. That is, the semiconductor package of the fifth embodiment may have a structure in which semiconductor devices are mounted on upper and lower sides, respectively.

In this case, the third semiconductor device 1330 may have a structure disposed on the lower surface of the second circuit board 1200 in the semiconductor package of FIG. 1c.

Referring to FIG. 1f, the semiconductor package according to the sixth embodiment includes a first circuit board 1100.

A first semiconductor device 1310 may be disposed on the first circuit board 1100. To this end, a first connection member 1410 may be disposed between the first circuit board 1100 and the first semiconductor device 1310.

In addition, the first circuit board 1100 may include a conductive coupling portion 1450. The conductive coupling portion 1450 may further protrude from the first circuit board 1100 toward the second semiconductor device 1320. The conductive coupling portion 1450 may be referred to as a bump or, alternatively, may also be referred to as a post. The conductive coupling portion 1450 may be disposed to have a protruding structure on an electrode disposed on an uppermost side of the first circuit board 1100.

A second semiconductor device 1320 may be disposed on the conductive coupling portion 1450 of the first circuit board 1100. In this case, the second semiconductor device 1320 may be connected to the first circuit board 1100 through the conductive coupling portion 1450. In addition, a second connection member 1420 may be disposed on the first semiconductor device 1310 and the second semiconductor device 1320.

Accordingly, the second semiconductor device 1320 may be electrically connected to the first semiconductor device 1310 through the second connection member 1420.

That is, the second semiconductor device 1320 may be connected to the first circuit board 1100 through the conductive coupling portion 1450, and may be also connected to the first semiconductor device 1310 through the second connection member 1420.

In this case, the second semiconductor device 1320 may receive a power signal through the conductive coupling portion 1450. Also, the second semiconductor device 1320 may transmit and receive a communication signal to and from the first semiconductor device 1310 through the second connection member 1420.

The semiconductor package according to the sixth embodiment may provide a power signal to the second semiconductor device 1320 through the conductive coupling portion 1450, thereby providing sufficient power for driving the second semiconductor device 1320. Accordingly, the embodiment may improve the driving characteristics of the second semiconductor device 1320. That is, the embodiment may solve a problem of insufficient power provided to the second semiconductor device 1320. Furthermore, in the embodiment, at least one of a power signal and a communication signal of the second semiconductor device 1320 is provided through different paths through the conductive coupling portion 1450 and the second connection member 1420. Through this, the embodiment can solve the problem that the communication signal is lost due to the power signal. For example, the embodiment may minimize mutual interference between communication signals of power signals.

Meanwhile, the second semiconductor device 1320 in the sixth embodiment may have a POP (Package On Package) structure and may be disposed on the first circuit board 1100. For example, the second semiconductor device 1320 may be a memory package including a memory chip. In addition, the memory package may be coupled on the conductive coupling portion 1450. In this case, the memory package may not be connected to the first semiconductor device 1310.

Meanwhile, the semiconductor package in the sixth embodiment may include a molding member 1460. The molding member 1460 may be disposed between the first circuit board 1100 and the second semiconductor device 1320. For example, the molding member 1460 may mold the first connection member 1410, the second connection member 1420, the first semiconductor device 1310, and the conductive coupling portion 1450.

Referring to FIG. 1g, the semiconductor package according to the seventh embodiment may include a first circuit board 1100, a first connection member 1410, a first connection member 1410, a semiconductor device 1300, and a third connection member 1430.

In this case, the semiconductor package of the seventh embodiment may differ from the semiconductor package of the fourth embodiment in that the first circuit board 1100 includes a plurality of substrate layers while the connection substrate 1110 is omitted.

The first circuit board 1100 includes a plurality of substrate layers. For example, the first circuit board 1100 may include a first substrate layer 1100A corresponding to a package substrate and a second substrate layer 1100B corresponding to a redistribution layer of the connecting substrate.

That is, the embodiment may configure the first circuit board 1100 by arranging the second substrate layer 1100B corresponding to the redistribution layer on the first substrate layer 1100A.

In other words, the semiconductor package of the seventh embodiment may include the first substrate layer 1100A and the second substrate layer 1100B formed integrally. A material of the insulating layer of the second substrate layer 1100B may be different from a material of the insulating layer of the first substrate layer 1100A. For example, the material of the insulating layer of the second substrate layer 1100B may include a photocurable material. For example, the second substrate layer 1100B may be a PID (Photo Imageable Dielectric). In addition, since the second substrate layer 1100B includes a photocurable material, miniaturization of the electrode is possible. Accordingly, the seventh embodiment can form a second substrate layer 1100B by sequentially laminating an insulating layer of a photocurable material on a first substrate layer 1100A and forming a fine electrode on the insulating layer of the photocurable material. Through this, the second substrate layer 1100B can be a redistribution layer including a fine electrode.

### Circuit Board

A circuit board of the embodiment is described below.

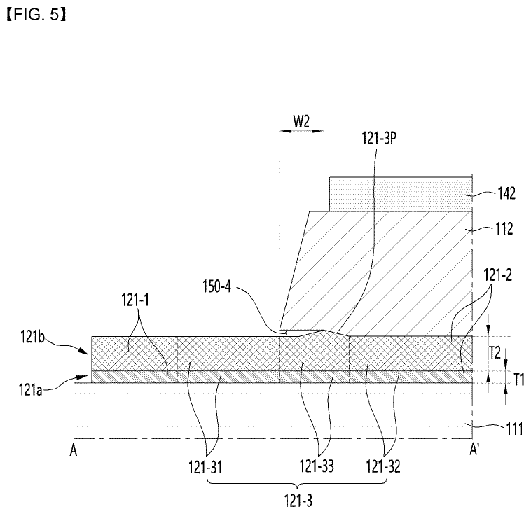

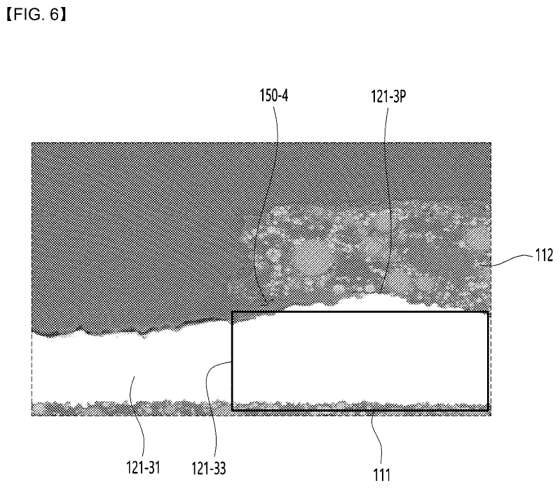

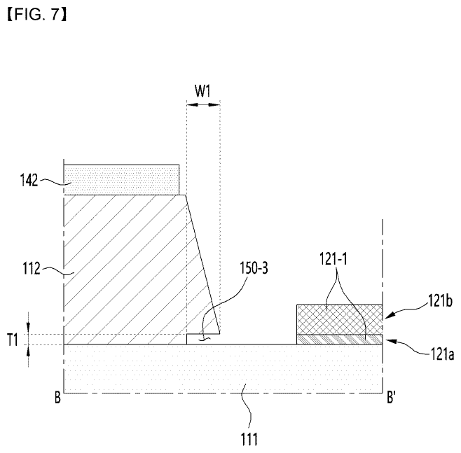

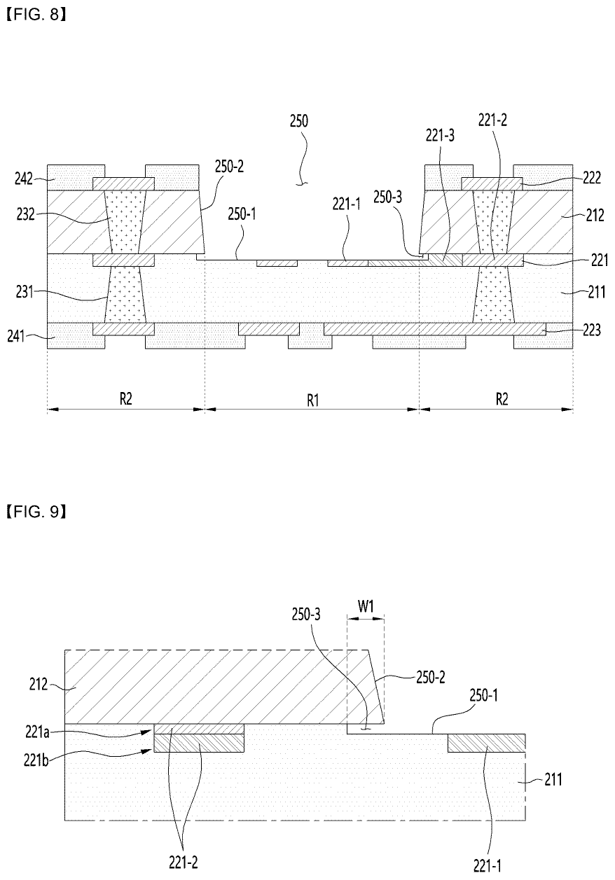

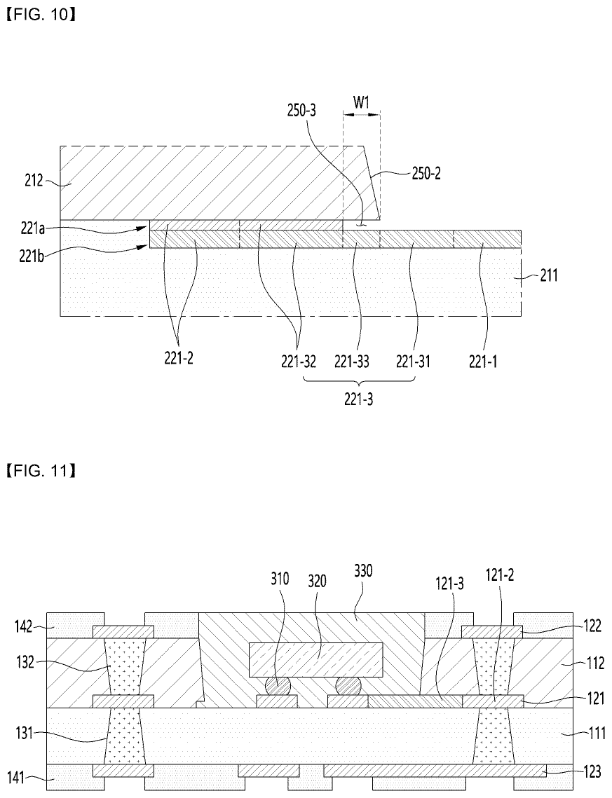

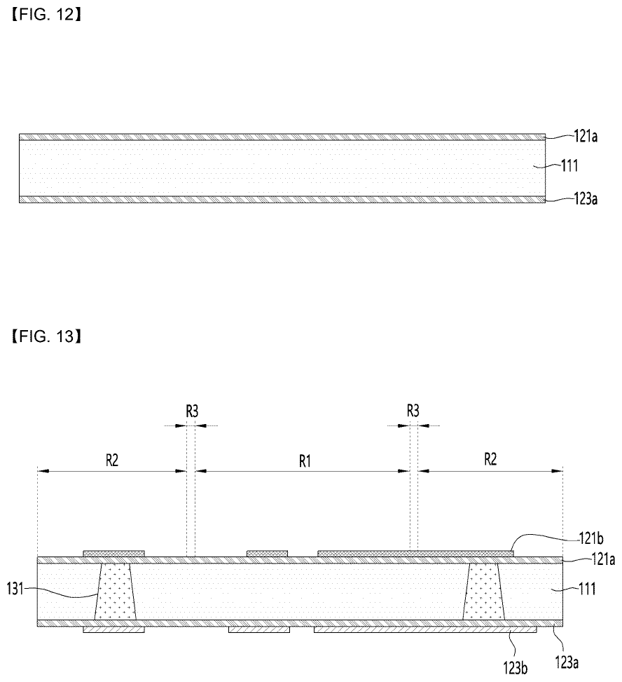

FIG. 2 is a cross-sectional view showing a circuit board according to a first embodiment, FIG. 3 is a plan view showing a first insulating layer and a first circuit pattern layer in the circuit board of FIG. 2, FIG. 4 is a plan view showing a circuit board of FIG. 3 with some configurations removed, FIG. 5 is a cross-sectional view taken along a A-A′ direction of FIGS. 3 and 4, FIG. 6 is an optical microscope photograph of an actual product corresponding to FIG. 5, and FIG. 7 is a cross-sectional view taken along a B-B′ direction of FIGS. 3 and 4.

Before describing the circuit board of the embodiment, the circuit board described below may mean any one of the plurality of boards included in the semiconductor package.

Preferably, the circuit board of the embodiment described below may be any one of the first circuit board 1100 and the second circuit board 1200 included in the semiconductor package. In addition, at least one of the first circuit board 1100 and the second circuit board 1200 may include a cavity described below.

At this time, a connection member may be disposed in the cavity.

When the circuit board is the first circuit board 1100, the connection member may be any one of a connection substrate, a second circuit board, and a semiconductor device.

In addition, when the circuit board is the second circuit board 1200, the connection member may be any one of the semiconductor device and the connection substrate.

Referring to FIG. 2, the circuit board of the embodiment includes a plurality of insulating layers. Each of the plurality of insulating layers may have a single-layer structure, or alternatively, may be composed of multiple layers.

Specifically, the circuit board may include a first insulating layer 111 and a second insulating layer 112.

At this time, the first insulating layer 111 may have a single-layer structure as shown in FIG. 2, or alternatively, may have a multiple-layer structure.

The second insulating layer 112 is disposed on the first insulating layer 111. The second insulating layer 112 may have a single-layer structure, or alternatively, may have a multiple-layer structure. The second insulating layer 112 includes a cavity 150. In addition, when the second insulating layer 112 has a multiple-layer structure, the cavity 150 may pass through the multiple second insulating layers.

However, for the convenience of explanation, each of the first insulating layer 111 and the second insulating layer 112 is described below as having a single-layer structure.

In one embodiment, the first insulating layer 111 and the second insulating layer 112 may include a same insulating material.

In another embodiment, the first insulating layer 111 and the second insulating layer 112 may include different insulating materials. At this time, when the first insulating layer 111 has a multi-layer structure, all of the plurality of first insulating layers may include a same insulating material, or alternatively, may include different insulating materials. In addition, when the second insulating layer 112 has a multi-layer structure, all of the plurality of second insulating layers may include a same insulating material, or alternatively, may include different insulating materials.

At least one of the first insulating layer 111 and the second insulating layer 112 may be rigid or flexible. For example, at least one of the first insulating layer 111 and the second insulating layer 112 may include glass or plastic. For example, at least one of the first insulating layer 111 and the second insulating layer 112 may include chemically strengthened/semi-strengthened glass such as soda lime glass or aluminosilicate glass. For example, at least one of the first insulating layer 111 and the second insulating layer 112 may include a strengthened or flexible plastic such as polyimide (PI), polyethylene terephthalate (PET), propylene glycol (PPG), or polycarbonate (PC). For example, at least one of the first insulating layer 111 and the second insulating layer 112 may include sapphire. For example, the insulating layer 110 of the circuit board 100 may include an optically isotropic film. For example, at least one of the first insulating layer 111 and the second insulating layer 112 may include COC (Cyclic Olefin Copolymer), COP (Cyclic Olefin Polymer), photoisotropic polycarbonate (PC), or photoisotropic polymethyl methacrylate (PMMA). For example, at least one of the first insulating layer 111 and the second insulating layer 112 may be formed of a material including an inorganic filler and an insulating resin. For example, at least one of the first insulating layer 111 and the second insulating layer 112 may have a structure in which an inorganic filler of silica or alumina is disposed in a thermosetting resin or a thermoplastic resin.

Specifically, in one embodiment, the first insulating layer 111 may be a core layer including reinforcing fibers, and the second insulating layer 112 may not include reinforcing fibers. Therefore, the circuit board may be a core board.

In another embodiment, the circuit board may be a coreless board that does not include a core layer.

The first insulating layer 111 and the second insulating layer 112 of one embodiment may include an organic material that does not include a reinforcing member that has excellent processability, excellent rigidity, enables slimming of the circuit board, and enables miniaturization of the circuit pattern layer. The reinforcing member may also be referred to as a reinforcing fiber or glass fiber.

For example, the first insulating layer 111 and the second insulating layer 112 may use ABF (Ajinomoto Build-up Film), FR-4, BT (Bismaleimide Triazine), BT, etc.

At this time, when the first insulating layer 111 and the second insulating layer 112 of the circuit board are composed of ABF (Ajinomoto Build-up Film), warpage characteristics of the circuit board may be deteriorated.

Therefore, when the first insulating layer 111 and the second insulating layer 112 of another embodiment are composed of ABF (Ajinomoto Build-up Film), at least one ABF among the ABFs constituting the plurality of insulating layers of the circuit board may include a reinforcing material capable of improving the warpage characteristics.

For example, the circuit board may include a layer composed of a first ABF and a layer composed of a second ABF further including a reinforcing material in an ABF. At this time, the reinforcing material included in the second ABF may be glass fiber, or may include a GCP (Glass Core Primer) material, but is not limited thereto.

Meanwhile, the embodiment allows an electrode pattern such as a trace to be disposed in a region exposed through the cavity 150 while providing a cavity 150 in the second insulating layer 112. At this time, when the second insulating layer 112 including the cavity 150 includes a photocurable resin, there may be no significant restrictions on an arrangement of the electrode pattern.

This is because the photocurable resin can form a cavity through an exposure and development process, and therefore, a stopper is not required in a cavity formation process.

However, if the second insulating layer 112 includes a photocurable resin, the adhesion between the multiple insulating layers of the circuit board may be reduced. Specifically, if all of the multiple insulating layers included in the circuit board are composed of a photocurable resin, the rigidity of the circuit board may be reduced, and the warpage characteristics may be significantly reduced accordingly. In addition, if the first insulating layer 111 is composed of a thermosetting resin and the second insulating layer 112 is composed of a photocurable resin, the adhesion between the photocurable resin and the thermosetting resin may be reduced depending on the physical properties of the photocurable resin. That is, the photocurable resin has a higher curing shrinkage rate than the thermosetting resin. Furthermore, a content of ceramic particles such as SiO₂ provided in the photocurable resin is higher than a content of ceramic particles provided in the thermosetting resin. The adhesion between the thermosetting resin and the photocurable resin may be reduced due to such differences in physical properties.

In addition, when both the first insulating layer 111 and the second insulating layer 112 include a thermosetting resin, it is difficult to arrange an electrode pattern in a region exposed through the cavity 150. That is, a stopper must be included in order to form the cavity 150. In addition, when an electrode pattern is disposed in a region exposed through the cavity 150, a circuit short problem occurs in which a plurality of electrode patterns are electrically connected by the stopper. Therefore, in a conventional technology, when a cavity was provided in a thermosetting resin, it was difficult to place an electrode pattern in a region exposed through the cavity.

In contrast, the embodiment allows a pad and an electrode pattern connected to the pad to be disposed in a region exposed through the cavity 150 of the second insulating layer 112 while the second insulating layer 112 includes a thermosetting resin. This will be described in more detail below.

The first insulating layer 111 and the second insulating layer 112 may each have a thickness in a range of 10 μm to 60 μm. For example, the first insulating layer 111 and the second insulating layer 112 may each have a thickness in a range of 15 μm to 55 μm. For example, the first insulating layer 111 and the second insulating layer 112 may each have a thickness in a range of 20 μm to 50 μm. If the thickness of the first insulating layer 111 and the second insulating layer 112 is less than 10 μm, the circuit pattern layer included in the circuit board may not be reliably protected. If the thickness of each of the first insulating layer 111 and the second insulating layer 112 exceeds 60 μm, an overall thickness of the circuit board may increase. In addition, if the thickness of each of the first insulating layer 111 and the second insulating layer 112 exceeds 60 μm, a thickness of a circuit pattern layer or a through electrode may increase accordingly, and a loss of a signal transmitted through the circuit pattern may increase accordingly.

At this time, the thickness of the first insulating layer 111 and the second insulating layer 112 may correspond to a distance in a thickness direction between circuit pattern layers disposed in different layers.

For example, the thickness of the first insulating layer 111 may mean a vertical distance between a lower surface of a first circuit pattern layer 121 and an upper surface of a third circuit pattern layer 123. For example, the thickness of the second insulating layer 112 may mean a vertical straight distance in the thickness direction between an upper surface of a first circuit pattern layer 121 and a lower surface of a second circuit pattern layer 122.

The second insulating layer 112 may include a cavity 150. The cavity 150 may pass through upper and lower surfaces of the second insulating layer 112.

The cavity 150 may include a lower surface 150-1 adjacent to a lower surface of the second insulating layer 112. At this time, the cavity 150 passes through the second insulating layer 112. Therefore, the lower surface 150-1 of the cavity 150 may be a part of an upper surface of the first insulating layer 111 that vertically overlaps the cavity 150.

The cavity 150 may include a side wall 150-2 extending from a lower surface 150-1 toward an upper surface of the second insulating layer 112 with an incline. At this time, the side wall 150-2 may have a slope in which the width of the cavity 150 increases from the lower surface of the second insulating layer 112 to the upper surface of the second insulating layer 112. However, the embodiment is not limited thereto. For example, the side wall 150-2 may have a slope in which the width of the cavity 150 decreases from the lower surface of the second insulating layer 112 to the upper surface of the second insulating layer 112. Furthermore, although the drawing illustrates that the side wall 150-2 has one slope, the embodiment is not limited thereto. For example, the side wall 150-2 may include at least one inflection portion, and may be inclined with different slopes in the inflection portion.

The cavity 150 may include a concave portion 150-3 extending from a lower end of the side wall 150-2 connected to the lower surface 150-1 in a direction away from the cavity 150. For example, the concave portion 150-3 may be recessed in at the lower end of the side wall 150-2 of the second insulating layer 112 forming the cavity 150 in an inner side direction toward the second insulating layer 112. Therefore, the concave portion 150-3 may also be referred to an undercut, a cavity expansion region, or a recessed portion.

The concave portion 150-3 is located adjacent to an edge region of the lower surface 150-1. The concave portion 150-3 may be connected to the lower surface 150-1. Accordingly, a region of the upper surface of the first insulating layer 111 that vertically overlaps with the concave portion 150-3 may not be covered by the second insulating layer 112.

The concave portion 150-3 may be provided along an edge direction of the lower surface 150-1 in an edge region of the lower surface 150-1. For example, the lower surface 150-1 may mean a region of the upper surface of the first insulating layer 111 that vertically overlaps with the cavity 150 but does not vertically overlap with the first circuit pattern layer 121. In addition, the concave portion 150-3 may be provided entirely along the edge direction of the lower surface 150-1.

Accordingly, the first insulating layer 111 may be divided into a plurality of regions based on a horizontal direction. For example, the first insulating layer 111 may include a first region R1 that vertically overlaps the cavity 150. At this time, when the cavity 150 has different widths in a thickness direction of the second insulating layer 112, the first region R1 may mean a region that vertically overlaps a lower region of the cavity 150 corresponding to a lower portion of the side wall 150-2.

In addition, the first insulating layer 111 may include a second region R2 that does not vertically overlap the cavity 150. The second region R2 may mean a region of the upper surface of the first insulating layer 111 that is covered with the second insulating layer 112.

In addition, the first insulating layer 111 may include a third region R3 between the first region R1 and the second region R2. The third region R3 may mean a boundary region between the first region R1 and the second region R2. Preferably, the third region R3 may mean a region that vertically overlaps the concave portion 150-3.

Meanwhile, a circuit pattern layer is disposed on surfaces of the first insulating layer 111 and the second insulating layer 112.

For example, a first circuit pattern layer 121 may be disposed between an upper surface of the first insulating layer 111 and a lower surface of the second insulating layer 112. For example, a second circuit pattern layer 122 may be disposed on an upper surface of the second insulating layer 112. For example, a third circuit pattern layer 123 may be disposed on a lower surface of the first insulating layer 111.

The first circuit pattern layer 121 in the first embodiment may be disposed on the first insulating layer 111. For example, the first circuit pattern layer 121 may protrude on the upper surface of the first insulating layer 111.

The second circuit pattern layer 122 may protrude on the upper surface of the second insulating layer 112. The second circuit pattern layer 122 may mean an uppermost circuit pattern layer disposed at an uppermost side of the circuit board.

The third circuit pattern layer 123 may protrude below the lower surface of the first insulating layer 111. The third circuit pattern layer 123 may refer to a lowermost circuit pattern layer disposed at a lowermost side of the circuit board.

The first circuit pattern layer 121, the second circuit pattern layer 122, and the third circuit pattern layer 123 may each include a pad and a trace (or an electrode pattern) according to their functions. The pad may be a mounting pad on which a device or chip is mounted, or a terminal pad connected to an external substrate. The trace may be a long signal wiring line connecting between a plurality of pads. The trace is a fine pattern having a smaller width than the pad. For example, a spacing between the plurality of traces in the embodiment may be in a range of 2 μm to 15 μm, and a line width of each trace may be in a range of 2 μm to 15 μm.

The circuit pattern layers as described above may be formed of at least one metal material selected from gold (Au), silver (Ag), platinum (Pt), titanium (Ti), tin (Sn), copper (Cu), and zinc (Zn). In addition, the circuit pattern layers may be formed of a paste or solder paste including at least one metal material selected from gold (Au), silver (Ag), platinum (Pt), titanium (Ti), tin (Sn), copper (Cu), and zinc (Zn) having excellent bonding strength. Preferably, the first circuit pattern layer 121, the second circuit pattern layer 122, and the third circuit pattern layer 123 may be formed of copper (Cu) which has high electrical conductivity and is relatively inexpensive.

The first circuit pattern layer 121, the second circuit pattern layer 122, and the third circuit pattern layer 123 may each have a thickness in a range of 10 μm to 25 μm. For example, the first circuit pattern layer 121, the second circuit pattern layer 122, and the third circuit pattern layer 123 may each have a thickness in a range of 10 μm to 23 μm. The first circuit pattern layer 121, the second circuit pattern layer 122, and the third circuit pattern layer 123 may each have a thickness in a range of 10 μm to 20 μm.

If the thickness of each of the first circuit pattern layer 121, the second circuit pattern layer 122, and the third circuit pattern layer 123 is less than 10 μm, a resistance of the circuit pattern may increase, and thus a signal transmission efficiency may decrease. For example, if the thickness of each of the first circuit pattern layer 121, the second circuit pattern layer 122, and the third circuit pattern layer 123 is less than 10 μm, the signal transmission loss may increase. For example, if the thickness of each of the first circuit pattern layer 121, the second circuit pattern layer 122, and the third circuit pattern layer 123 exceeds 25 μm, the line width of the circuit patterns may increase, and thus an overall volume of the circuit board may increase.

The first circuit pattern layer 121, the second circuit pattern layer 122, and the third circuit pattern layer 123 may be manufactured using conventional printed circuit board manufacturing processes such as an additive process, a subtractive process, a modified semi-additive process (MSAP), and a semi-additive process (SAP), and a detailed description thereof is omitted herein.

The first circuit pattern layer 121 may include a plurality of pad and electrode patterns.

The first circuit pattern layer 121 may include a first pad 121-1 disposed on the first region R1 of the first insulating layer 111. The first pad 121-1 may be vertically overlapped with the cavity 150. Therefore, the first pad 121-1 may not be in contact with the second insulating layer 112.

The first circuit pattern layer 121 may include a second pad 121-2 disposed on the second region R2 of the first insulating layer 111. The second pad 121-2 may not be vertically overlapped with the cavity 150. Therefore, the second pad 121-2 may be covered with the second insulating layer 112.

The first circuit pattern layer 121 may include an electrode pattern 121-3. The electrode pattern 121-3 may be disposed in the first region R1, the second region R2, and the third region R3 of the first insulating layer 111.

At this time, the first circuit pattern layer 121 may include a plurality of electrode patterns. In addition, the electrode pattern 121-3 described above may mean an electrode pattern that is directly connected to the first pad 121-1 among the plurality of electrode patterns.

The electrode pattern 121-3 may directly connect between the first pad 121-1 disposed in the first region R1 and the second pad 121-2 disposed in the second region R2. That is, the embodiment forms a cavity 150 in the second insulating layer 112 including the thermosetting resin, and arranges the electrode pattern 121-3 on an upper surface of the first insulating layer 111 exposed through the formed cavity 150. Accordingly, in the embodiment, the first pad 121-1 in the first region R1 and the second pad 121-2 disposed in the second region R2 can be directly connected to each other by the electrode pattern 121-3 on the upper surface of the first insulating layer 111. Therefore, the embodiment can improve the adhesion between the plurality of insulating layers of the circuit board by the first insulating layer 111 and the second insulating layer 112 including the thermosetting resin. In addition, the embodiment can improve a circuit integration density while improving the adhesion. That is, in a conventional technology, when a cavity is provided in a thermosetting resin, the first pad 121-1 and the second pad 121-2 is connected to each other through at least one through electrode. Accordingly, a signal transmission distance between the first pad 121-1 and the second pad 121-2 increased, and thus the signal transmission loss increased. In contrast, the embodiment directly connects the first pad 121-1 and the second pad 121-2 by using the electrode pattern 121-3 without the through electrode. Therefore, the embodiment can reduce a signal transmission distance, and thus the signal transmission loss can be minimized. Accordingly, the embodiment can improve the electrical reliability of the circuit board.

At this time, at least a part of the electrode pattern 121-3 is connected to the concave portion 150-3. Here, being connected to the concave portion 150-3 may mean that the concave portion 150-3 and the electrode pattern 121-3 overlap each other along the edge direction. For example, the concave portion 150-3 vertically overlaps the third region R3 of the first insulating layer 111. In addition, the electrode pattern 121-3 includes a portion disposed in the third region R3. At this time, a side surface of the portion of the electrode pattern 121-3 disposed in the third region R3 may be exposed through the concave portion 150-3. For example, at this time, the side surface of the portion of the electrode pattern 121-3 disposed in the third region R3 may not be covered with the second insulating layer 112 through the concave portion 150-3.

Meanwhile, in one embodiment, thicknesses of the first pad 121-1, the second pad 121-2, and the electrode pattern 121-3 may be the same.

In another embodiment, at least one of the first pad 121-1, the second pad 121-2, and the electrode pattern 121-3 may have a different thickness from at least one other. For example, a thickness of the first pad 121-1 may be different from a thickness of the second pad 121-2. For example, the thickness of the first pad 121-1 may be smaller than the thickness of the second pad 121-2. This may be because an etching amount of a seed layer of the first pad 121-1 is greater than an etching amount of a seed layer of the second pad 121-2. In other words, the first pad 121-1 and the second pad 121-2 include seed layers having a same thickness. In addition, thicknesses of the first pad 121-1 and the second pad 121-2 may be reduced in an etching process of the seed layer, respectively. At this time, the etching process of the seed layer of the first pad 121-1 is performed together with the etching process of a stopper corresponding to the concave portion 150-3. At this time, the embodiment may etch the stopper with a relatively large etching amount in order to prevent the stopper from remaining during the etching process of the stopper. Accordingly, the thickness of the first pad 121-1 may be smaller than the thickness of the second pad 121-2.

The circuit board of the embodiment includes a through electrode. The through electrode may have a function of electrically connecting circuit pattern layers disposed on different layers to each other. The through electrode may also be called a ‘via’.

The through electrode passes through the first insulating layer 111 and the second insulating layer 112 included in the circuit board, and thus can electrically connect circuit patterns disposed on different layers. At this time, the through electrode can be formed by passing through only one insulating layer, or alternatively, can be formed by passing through at least two or more insulating layers in common.

For example, the circuit board includes the first through electrode 131. The first through electrode 131 can be formed by passing through the first insulating layer 111. The first through electrode 131 can electrically connect between the first circuit pattern layer 121 and the third circuit pattern layer 123. For example, an upper surface of the first through electrode 131 can be directly connected to a lower surface of the first circuit pattern layer 121. For example, a lower surface of the first through electrode 131 may be directly connected to the third circuit pattern layer 123.

Accordingly, the first circuit pattern layer 121 and the third circuit pattern layer 123 may be electrically connected to each other through the first through electrode 131 to transmit a signal.

For example, the circuit board includes the second through electrode 132. The second through electrode 132 may be formed by passing through the second insulating layer 112. The second through electrode 132 may electrically connect the first circuit pattern layer 121 and the second circuit pattern layer 122. For example, a lower surface of the second through electrode 132 may be directly connected to the first circuit pattern layer 121. For example, an upper surface of the second through electrode 132 may be directly connected to the second circuit pattern layer 122. Accordingly, the first circuit pattern layer 121 and the second circuit pattern layer 122 can be directly electrically connected to each other through the second through electrode 132 to transmit a signal.

The first through electrode 131 and the second through electrode 132 can be formed by forming a through hole passing through the first insulating layer 111 and the second insulating layer 112 and filling inside of the formed through hole with a conductive material.

The through hole can be formed by any one of mechanical, laser, and chemical processing methods. When the through hole is formed by mechanical processing, methods such as milling, drilling, and routing can be used, and when the through hole is formed by laser processing, a UV or CO2 laser method can be used, and when the through hole is formed by chemical processing, at least one of the plurality of insulating layers can be opened using a chemical agent including aminosilane, ketones, etc.

When the through hole is formed, the inside of the through hole can be filled with a conductive material to form the first through electrode 131 and the second through electrode 132. The metal material forming the first through electrode 131 and the second through electrode 132 can be any one material selected from copper (Cu), silver (Ag), tin (Sn), gold (Au), nickel (Ni), and palladium (Pd), and the filling of the conductive material can use any one of electroless plating, electrolytic plating, screen printing, sputtering, evaporation, inkjetting, and dispensing, or a combination thereof.

Meanwhile, the circuit board of the embodiment can include a first protective layer 141 and a second protective layer 142. The first protective layer 141 and the second protective layer 142 can be disposed on an outermost side of the circuit board.

For example, the first protective layer 141 may be disposed on a first outermost or lowermost side of the circuit board. For example, the first protective layer 141 may be disposed on a lower surface of the first insulating layer 111.

For example, the second protective layer 142 may be disposed on a second outermost or uppermost side of the circuit board. For example, the second protective layer 142 may be disposed on an upper surface of the second insulating layer 112.

The first protective layer 141 may include at least one opening (not shown). For example, the first protective layer 141 may include an opening that vertically overlaps at least one of the third circuit pattern layers 123. For example, the first protective layer 141 may include an opening that vertically overlaps a terminal pad (not shown) of the third circuit pattern layer 123 on which a conductive coupling portion for connection with an external substrate is disposed.

The second protective layer 142 may include at least one opening (not shown). For example, the second protective layer 142 may include an opening that vertically overlaps at least one of the second circuit pattern layers 122. For example, the second protective layer 142 may include an opening that vertically overlaps a terminal pad (not shown) of the second circuit pattern layer 122 on which a conductive coupling portion for connection with a memory substrate or an interposer substrate is to be disposed. In addition, the second protective layer 142 may include a through hole (not shown) that vertically overlaps a cavity 121 of the second insulating layer 112.

The first protective layer 141 and the second protective layer 142 may include an insulating material. The first protective layer 141 and the second protective layer 142 may include various materials that can be applied and then cured by heating to protect surfaces of the insulating layers and surfaces of the circuit pattern layers. The first protective layer 141 and the second protective layer 142 may be resist layers. For example, the first protective layer 141 and the second protective layer 142 may be solder resist layers including organic polymer materials. As an example, the first protective layer 141 and the second protective layer 142 may include an epoxy acrylate series resin. In detail, the first protective layer 141 and the second protective layer 142 may include a resin, a curing agent, a photoinitiator, a pigment, a solvent, a filler, an additive, an acrylic series monomer, etc. However, the embodiment is not limited thereto, and the first protective layer 141 and the second protective layer 142 may be any one of a photo solder resist layer, a cover-lay, and a polymer material.

A thickness of the first protective layer 141 and the second protective layer 142 may be 1 μm to 20 μm. The thickness of the first protective layer 141 and the second protective layer 142 may be 1 μm to 15 μm. For example, the thickness of the first protective layer 141 and the second protective layer 142 may be 5 μm to 20 μm. If the thickness of the first protective layer 141 and the second protective layer 142 exceeds 20 μm, a thickness of the circuit board may increase. If the thickness of the first protective layer 141 and the second protective layer 142 is less than 1 μm, electrical reliability or physical reliability may be reduced because the circuit pattern layers included in the circuit board are not stably protected.

At this time, although not shown in the drawing, a surface treatment layer (not shown) may be disposed in the opening of the first protective layer 141 and the second protective layer 142 that vertically overlaps the second circuit pattern layer 122 and the third circuit pattern layer 123. The surface treatment layer may be formed to prevent corrosion and oxidation of surfaces of the third circuit pattern layer 123 vertically overlapping the opening of the first protective layer 141 and the second circuit pattern layer 122 vertically overlapping the opening of the second protective layer 142 while improving soldering characteristics.

The surface treatment layer may be an OSP (Organic Solderability Preservative) layer. For example, the surface treatment layer may be an organic layer formed of an organic material such as benzimidazole.

However, the embodiment is not limited thereto. For example, the surface treatment layer may be a plating layer. For example, the surface treatment layer may include at least one of a nickel (Ni) plating layer, a palladium (Pd) plating layer, and a gold (Au) plating layer.

Hereinafter, a structure of the cavity 150 of the embodiment and an arrangement structure of the first circuit pattern layer 121 according to the structure of the cavity 150 will be described in more detail.

Referring to FIG. 3, the first circuit pattern layer 121 may be disposed on the first insulating layer 111. In addition, as described above, the first circuit pattern layer 121 may include a first pad 121-1, a second pad 121-2, and an electrode pattern 121-3.

The first pad 121-1 may be disposed in a first region R1 that vertically overlaps the cavity 150.

In addition, the second pad 121-2 may be disposed in the second region R2 that does not vertically overlap with the cavity 150.

In addition, the electrode pattern 121-3 may be disposed in the first region R1, the second region R2, and the third region R3. The electrode pattern 121-3 may directly connect the first pad 121-1 and the second pad 121-2 on the first insulating layer 111. For example, one end of the electrode pattern 121-3 may be directly connected to the first pad 121-1, and another end of the electrode pattern 121-3 may be directly connected to the second pad 121-2.

At this time, the drawing shows that each of the first pad 121-1, the second pad 121-2, and the electrode pattern 121-3 is provided with 6, but it is not limited thereto. For example, each of the first pad 121-1, the second pad 121-2, and the electrode pattern 121-3 may have 5 or less or 7 or more. In addition, a number of the first pad 121-1, the second pad 121-2, and the electrode pattern 121-3 may be different from each other. Therefore, at least one of the plurality of first pads 121-1 may not be directly connected to the second pad 121-2.

In addition, referring to FIG. 4, a second insulating layer 112 may be disposed on the first insulating layer 111. The second insulating layer 112 may include a cavity 150. The cavity 150 may pass through the second insulating layer 112.

Therefore, the first pad 121-1 may not vertically overlap with the second insulating layer 112. For example, the first pad 121-1 may vertically overlap with the cavity 150.

In addition, the second pad 121-2 may vertically overlap with the second insulating layer 112. For example, the second pad 121-2 may not vertically overlap with the cavity 150.

Meanwhile, the electrode pattern 121-3 may be divided into a plurality of portions depending on the position. At this time, being divided into a plurality of portions may mean that one electrode pattern directly connecting one first pad and one second pad is divided into a plurality of portions.

The electrode pattern 121-3 may include a first portion 121-31 that vertically overlaps with the cavity 150 and connected to the first pad 121-1. The first portion 121-31 of the electrode pattern 121-3 may not vertically overlap with the second insulating layer 112. For example, the first portion 121-31 of the electrode pattern 121-3 may not be covered with the second insulating layer 112.

In addition, the electrode pattern 121-3 may include a second portion 121-32 that vertically overlaps with the second insulating layer 112. The second portion 121-32 of the electrode pattern 121-3 may not vertically overlap with the cavity 150. For example, the second portion 121-32 of the electrode pattern 121-3 may be covered with the second insulating layer 112.

The electrode pattern 121-3 may further include a third portion 121-33 between the first portion 121-31 and the second portion 121-32.

The third portion 121-33 of the electrode pattern 121-3 may mean a portion adjacent to an edge region of the lower surface 150-1 of the cavity 150. For example, the third portion 121-33 of the electrode pattern 121-3 may mean a portion located at a boundary region of the cavity 150. For example, the third portion 121-33 of the electrode pattern 121-3 may mean a portion located adjacent to the concave portion 150-3. For example, the third portion 121-33 of the electrode pattern 121-3 may mean a portion disposed in the third region R3, which is a boundary region between the first region R1 and the second region R2.

Meanwhile, the concave portion 150-3 may be provided along an edge direction of the lower surface 150-1 in an edge region of the lower surface 150-1. For example, the concave portion 150-3 may be concave at a lower end of the side wall 150-2 adjacent to the edge region of the lower surface 150-1 in an inner side direction of the second insulating layer 112. To summarize, a lower end portion of the side wall 150-2 of the second insulating layer 112 constituting the cavity 150 may be provided with a concave portion 150-3 that is recessed toward an inner side along the edge direction of the lower surface 150-1.

At this time, the drawing shows that the concave portion 150-3 is not provided in a region that vertically overlaps the electrode pattern 121-3 among the lower end portion of the side wall 150-2, but it is not limited thereto. This will be described as follows.

Referring to FIGS. 5 to 7, the first circuit pattern layer 121 includes a plurality of metal layers.

The first circuit pattern layer 121 includes a first metal layer 121a disposed on the first insulating layer 111. The first metal layer 121a may mean a seed layer for electrolytic plating the second metal layer 121b of the first circuit pattern layer 121.

For example, the first metal layer 121a may be a chemical copper plating layer. For example, the first metal layer 121a may be a copper foil layer (Cu foil).

In one embodiment, the first metal layer 121a may include only one of the chemical copper plating layer and the copper foil layer.

In another embodiment, the first metal layer 121a may include both the chemical copper plating layer and the copper foil layer.

A thickness T1 of the first metal layer 121a may satisfy a range of 1.0 μm to 4.0 μm. Preferably, the thickness T1 of the first metal layer 121a may satisfy a range of 1.2 μm to 3.5 μm. More preferably, the thickness T1 of the first metal layer 121a may satisfy a range of 1.5 μm to 3.0 μm.

If the thickness T1 of the first metal layer 121a is less than 1.0 μm, the first metal layer 121a may not function as a seed layer. If the thickness T1 of the first metal layer 121a is less than 1.0 μm, it may be difficult to form a first metal layer 121a with a uniform thickness on the upper surface of the first insulating layer 111.

If the thickness T1 of the first metal layer 121a exceeds 4.0 μm, a time required to etch the first metal layer 121a may increase. If the thickness T1 of the first metal layer 121a exceeds 4.0 μm, deformation of the second metal layer 121b may occur during etching of the first metal layer 121a. The deformation of the second metal layer 121b may mean that the difference between a width of an upper surface and a width of a lower surface of the second metal layer 121b increases as a side portion of the first metal layer 121a is also etched. In addition, if the thickness T1 of the first metal layer 121a exceeds 4.0 μm, the reliability of an etching process of the first metal layer 121a used as a stopper in the cavity forming process may deteriorate. For example, a part of the first metal layer 121a is used as a stopper in a process of forming the cavity. In addition, the first metal layer 121a used as the stopper is removed after the formation of the cavity 150 is completed. At this time, if the thickness T1 of the first metal layer 121a exceeds 4.0 μm, a part of the stopper in the portion corresponding to the concave portion 150-3 may not be removed during the etching process of the stopper. In addition, if a part of the stopper is not removed, an electrical short problem may occur in which a plurality of adjacent electrode patterns are connected to each other by the stopper.

A second metal layer 121b is disposed on the first metal layer 121a. The second metal layer 121b may be an electroplated layer in which the first metal layer 121a is electroplated as a seed layer.

A thickness T2 of the second metal layer 121b may correspond to a value obtained by subtracting the thickness of the first metal layer 121a from a total thickness of the first circuit pattern layer 121. Since the total thickness of the first circuit pattern layer 121 has already been described above, a detailed description thereof will be omitted.

Meanwhile, each of the first pad 121-1, the second pad 121-2, and the electrode pattern 121-3 of the first circuit pattern layer 121 includes the first metal layer 121a and the second metal layer 121b. At this time, the first pad 121-1, the second pad 121-2 and the electrode pattern 121-3 mean one circuit pattern including a same first metal layer 121a and a same second metal layer 121b, and may be distinguished only by the arrangement position and function.

The electrode pattern 121-3 includes a first portion 121-31, a second portion 121-32 and a third portion 121-33 as described above.

At this time, the third portion 121-33 of the electrode pattern 121-3 may include a region having a varying thickness. For example, at least a part of the third portion 121-31 of the electrode pattern 121-3 may include a part having a thickness greater than a thickness of the first portion 121-31. For example, at least a part of the third portion 121-33 of the electrode pattern 121-3 may include a part having a thickness greater than that of the second portion 121-32.

For example, at least a part of an upper surface of the third portion 121-33 of the electrode pattern 121-3 may include a part positioned higher than that of the first portion 121-31. For example, at least a part of the upper surface of the third portion 121-33 of the electrode pattern 121-3 may include a part positioned higher than that of the second portion 121-32.

For example, the third portion 121-32 of the electrode pattern 121-3 may include a protrusion 121-3P whose thickness or height changes from the first portion 121-31 to the second portion 121-32 or from the second portion 121-32 to the first portion 121-31.

In addition, the protrusion 121-3P may include a first part whose height or thickness increases from the first portion 121-31 to the second portion 121-32, and a second part whose height or thickness decreases based on the first part.

At this time, the embodiment etches the first metal layer 121a of the first circuit pattern layer 121 in multiple steps in a manufacturing process of the circuit board.

That is, in the embodiment, the first metal layer 121a of the first circuit pattern layer 121 disposed in the second region R2 is removed in a first etching process before the cavity 150 of the second insulating layer 112 is formed.

In addition, the first metal layer 121a of the first circuit pattern layer 121 disposed in the first region R1 and the third region R3 is removed in a second etching process after the cavity 150 is formed.

At this time, the second metal layer of the electrode pattern 121-3 may also be etched in two steps corresponding to the first metal layer. In addition, under ideal conditions, a part of the second metal layer of the electrode pattern 121-3 may be removed in the first etching process, and a remaining part of the second metal layer of the electrode pattern 121-3 may be removed in the second etching process. However, due to process errors in the electrode pattern 121-3, it may be difficult to accurately distinguish between a portion where the first etching process is performed and a portion where the second etching process is performed.

Accordingly, some of the second metal layers of the electrode pattern 121-3 may not be etched in both the first etching process and the second etching process. In addition, a portion where the etching is not performed may be provided as the protrusion 121-3P. The protrusion 121-3P may be provided at a boundary between the third region R3 and the second region R2 in the third portion 121-32 of the electrode pattern 121-3.

In addition, conversely, some of the second metal layers of the electrode pattern 121-3 may be etched in both the first etching process and the second etching process. In addition, in a case of the above conditions, the third portion 121-32 of the electrode pattern 121-3 may be provided with a concave portion (not shown) instead of the protrusion 121-3P.

In addition, the third portion 121-33 of the electrode pattern 121-3 is adjacent to the concave portion 150-3.

At this time, at least a part of the upper surface of the third portion 121-33 of the electrode pattern 121-3 may vertically overlap with the second insulating layer 112 and may not contact the second insulating layer 112.

For example, a second concave portion 150-4 may be provided in a region of the lower end portion of the side wall 150-2 of the cavity 150 of the second insulating layer 112 that vertically overlaps with the electrode pattern 121-3. Accordingly, the concave portion 150-3 described above may be referred to as a first concave portion. Hereinafter, the concave portion 150-3 will be described as the ‘first concave portion’.

The first concave portion 150-3 and the second concave portion 150-4 are provided at a lower end of the side wall 150-2 of the second insulating layer 112 adjacent to an edge region of the lower surface 150-1.

At this time, the first concave portion 150-3 and the second concave portion 150-4 may have a step. That is, the first concave portion 150-3 is provided in a region of a lower end of the side wall 150-2 that does not vertically overlap with the electrode pattern 121-3.

In contrast, the second concave portion 150-4 is provided in a region of the lower end of the side wall 150-2 that vertically overlaps with the electrode pattern 121-3. Accordingly, the first concave portion 150-3 and the second concave portion 150-4 may have a step equal to a thickness of the electrode pattern 121-3.

Accordingly, the first concave portion 150-3 and the second concave portion 150-4 may be recessed in the entire region of the lower portion of the side wall 150-2 toward an inner side of the second insulating layer 112 along the edge direction of the lower surface 150-1.

The first concave portion 150-3 may have a first horizontal distance W1.

The first horizontal distance W1 may mean a horizontal distance from the lower end portion of the side wall 150-2 adjacent to the first concave portion 150-3 to an innermost side surface of the first concave portion 150-3. In addition, the first concave portion 150-3 is a space where the first metal layer used as a stopper in the process for forming the cavity 150 is removed.

The first horizontal distance W1 can satisfy a range of 5 μm to 17 μm. Preferably, the first horizontal distance W1 can satisfy a range of 7 μm to 15 μm. More preferably, the first horizontal distance W1 can satisfy a range of 8 μm to 13 μm.

If the first horizontal distance W1 is less than 5 μm, the cavity 150 may be processed up to a region where the stopper is not provided due to a process error in the process for forming the cavity 150. In this case, a part of the upper surface of the first insulating layer 111 may also be processed in a process for forming the cavity. At this time, the first insulating layer 111 includes reinforcing fibers. In addition, the reinforcing fibers may be exposed by the processing, and thus physical reliability problems and electrical reliability problems may occur.

In addition, if the first horizontal distance W1 exceeds 17 μm, a part of the stopper may not be removed in a stopper removal process after the cavity 150 is formed. For example, the embodiment removes all of the stopper by utilizing the overetching phenomenon in the stopper removal process. That is, if the stopper removal process is performed after the cavity 150 is formed, only the portion vertically overlapping the cavity 150 is removed by etching under general conditions. However, the embodiment sets an overetching condition in the stopper removal process, and removes the stopper according to the set overetching condition. In addition, when the stopper is removed according to the overetching condition, the stopper covered by the second insulating layer 112 in a region adjacent to the cavity 150 is also removed. At this time, a fact that the first horizontal distance W1 exceeds 17 μm may mean that the overetching condition is set too excessively, which may cause damage to the first pad 121-1. In addition, a fact that the first horizontal distance W1 exceeds 17 μm may mean that a part of the stopper may not be removed even under the overetching condition for removing the stopper. In addition, if a part of the stopper is not removed, an electrical reliability problem such as a circuit short may occur.

Meanwhile, the first concave portion 150-3 is a space where the first metal layer 121a is removed, and accordingly, a vertical distance T1 of the first concave portion 150-3 may correspond to a thickness T1 of the first metal layer 121a.

In addition, the second concave portion 150-4 may have a second horizontal distance W2. At this time, the second horizontal distance W2 of the second concave portion 150-4 may be greater than or equal to the first horizontal distance W1 of the first concave portion 150-3. Preferably, the second horizontal distance W2 of the second concave portion 150-4 may be greater than the first horizontal distance W1 of the first concave portion 150-3.

This means that the first horizontal distance W1 and the second horizontal distance W2 being equal to each other can mean that overetching has occurred only to a portion where the stopper is located under the overetching conditions for removing the stopper. In this case, there may be a problem that a portion of the stopper is not removed in some cases. Therefore, the embodiment allows the second horizontal distance W2 to be greater than the first horizontal distance W1. In addition, a fact that the second horizontal distance W2 is greater than the first horizontal distance W1 can mean that the over etching occurs to portions other than a portion where the stopper is located under the over-etching condition for removing the stopper. Accordingly, the stopper may be completely removed, thereby improving the electrical reliability of the circuit board.

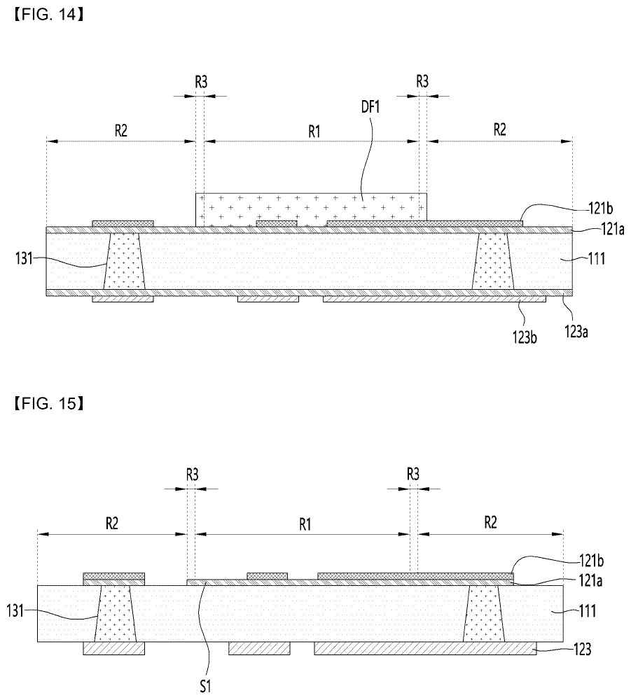

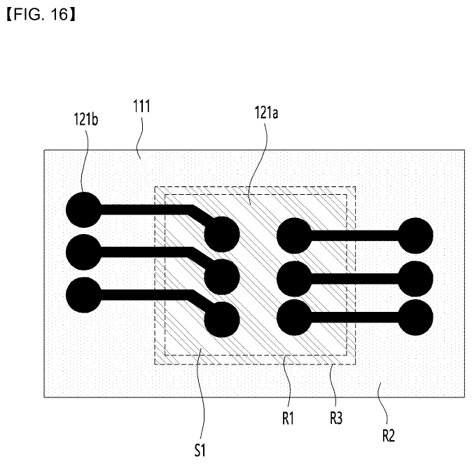

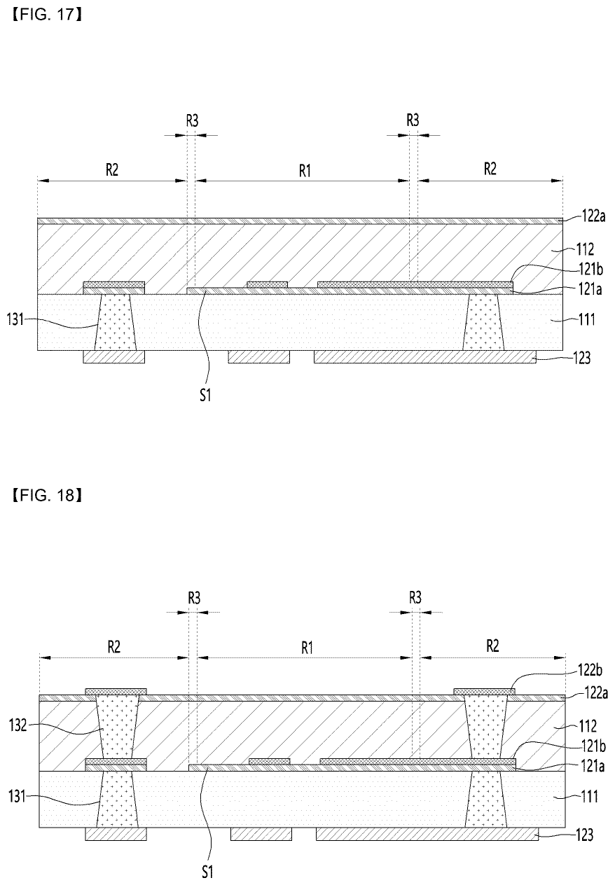

FIG. 8 is a cross-sectional view showing a circuit board according to a second embodiment, FIG. 9 is an enlarged view showing a partial region of the cavity of FIG. 8, and FIG. 10 is an enlarged view showing another partial region of the cavity of FIG. 8.

Referring to FIGS. 8 to 10, the circuit board of the second embodiment includes a first insulating layer 211, a second insulating layer 212, a first circuit pattern layer 221, a second circuit pattern layer 222, a third circuit pattern layer 223, a first through electrode 231, a second through electrode 232, a first protective layer 241, and a second protective layer 242. In addition, the second insulating layer 212 may be provided with a cavity 250 including a lower surface 250-1 and a side wall 250-2.

At this time, the circuit board of the second embodiment may have a structure in which the cavity is provided in the first insulating layer of the first embodiment when the circuit board of the first embodiment is turned upside down.

Therefore, the circuit board of the second embodiment may be different in a position of a first concave portion 250-3 and a layer structure of the first circuit pattern layer 221.

Specifically, the first concave portion in the first embodiment is provided at a side wall of the second insulating layer.

Unlike this, the first concave portion 250-3 in the second embodiment may be provided at the upper surface of the first insulating layer 211.

That is, the first circuit pattern layer 221 includes a first metal layer 221a and a second metal layer 221b.

At this time, in the circuit board of the first embodiment, the second metal layer of the first circuit pattern layer is positioned closer to the cavity than the first metal layer.

In contrast, the circuit board of the second embodiment has the first metal layer 221a positioned closer to the cavity 250 than the second metal layer 221b of the first circuit pattern layer 221.

Therefore, in the circuit board of the second embodiment, the upper surface of the first insulating layer 211 may have a step. For example, an upper surface of the first insulating layer 211 in a region vertically overlapping the cavity 250 may have a first height. In addition, an upper surface of the first insulating layer 211 in a region that does not vertically overlap with the cavity 250 may have a second height higher than the first height. At this time, a portion of the upper surface of the first insulating layer 211 that is not vertically overlapped with the cavity 250 and is adjacent to the cavity 250 may include a first concave portion 250-3 having the first height. That is, the cavity 250 is formed in a state where the first metal layer 221a of the first circuit pattern layer 221 is disposed at a position corresponding to the first concave portion 250-3. In addition, as a part of the first metal layer 221a is removed after the cavity 250 is formed, an upper surface of the first insulating layer 211 may have a step corresponding to the concave portion 250-3.

That is, the first concave portion 250-3 of the second embodiment may be recessed from the lower end of the side wall 150-2 of the cavity 250 toward the inner side of the first insulating layer 211.

To summarize, the first concave portion and the second concave portion of the first embodiment have a structure recess from the lower end of the side wall of the cavity toward the inner side of the second insulating layer. Accordingly, a lower surface of the second insulating layer of the first embodiment has a step corresponding to the first and second concave portions.

Unlike this, the first concave portion 250-3 of the second embodiment may have a structure recessed from the lower end of the side wall 150-2 of the cavity 250 toward the inner side of the first insulating layer 211. Accordingly, the upper surface of the first insulating layer 211 may have a step corresponding to the first concave portion 250-3.

Meanwhile, the first circuit pattern layer 221 includes a first pad 221-1, a second pad 221-2, and an electrode pattern 221-3. In addition, the electrode pattern 221-3 may include a first portion 221-31, a second portion 221-32, and a third portion 221-33.

At this time, the first pad 221-1, the second pad 221-2, and the electrode pattern 221-3 may have different thicknesses. For example, the first pad 221-1, the second pad 221-2, and the electrode pattern 221-3 may have different layer structures.

Preferably, the first circuit pattern layer 221 may include a first metal layer 221a and a second metal layer 221b.

At this time, the first metal layer of the first pad 221-1 is used as a stopper in a process of forming the cavity 250. Accordingly, the first pad 221-1 may include only the second metal layer excluding the first metal layer.

Unlike this, the second pad 221-2 may include both the first metal layer 221a and the second metal layer 221b.

Meanwhile, the electrode pattern 221-3 may have different layer structures or thicknesses depending on the location.

The first portion 221-31 of the electrode pattern 221-3 may include only the second metal layer 221b. This is because the first metal layer 221a of the first portion 221-31 of the electrode pattern 221-3 is used as a stopper in a process of forming the cavity 250.

In addition, the second portion 221-32 of the electrode pattern 221-3 may include both the first metal layer 221a and the second metal layer 221b.

Meanwhile, the third portion 221-33 of the electrode pattern 221-3 may include only the second metal layer 221b. This is because overetching occurs in a process of removing the first metal layer of the first portion 221-31 of the electrode pattern 221-3 by etching, and thus the first metal layer 221a of the third portion 221-33 of the electrode pattern 221-3 is removed.

The circuit board of the embodiment comprises a first insulating layer, a first circuit pattern layer disposed on the first insulating layer; and a second insulating layer disposed on the first insulating layer and the first circuit pattern layer. At this time, the second insulating layer includes a cavity passing through an upper surface and a lower surface. In addition, the first circuit pattern layer may include a first pad disposed in a first region vertically overlapping the cavity; a second pad disposed in a second region not vertically overlapping the cavity; and an electrode pattern disposed in the first region and the second region and connecting the first pad and the second pad.

That is, the embodiment arranges an electrode pattern directly connecting the first pad and the second pad on the first insulating layer. Accordingly, the embodiment can reduce a signal transmission distance between the first pad and the second pad. Furthermore, the embodiment can minimize call transmission loss by reducing the signal transmission distance. Accordingly, the embodiment can improve electrical characteristics of the circuit board and the semiconductor package including the same.

In addition, the embodiment can improve the circuit integration by arranging the electrode pattern in a region corresponding to the cavity.

Meanwhile, the second insulating layer including the cavity includes a thermosetting resin. In addition, the embodiment can arrange the electrode pattern while the second insulating layer includes a thermosetting resin. The embodiment can improve the adhesion between a plurality of insulating layers by forming the insulating layer using a thermosetting resin. Accordingly, the embodiment can improve physical characteristics of the circuit board and the semiconductor package including the same.

Meanwhile, a concave portion can be provided along a circumferential direction of a lower surface of the cavity at a lower end of the side wall of the cavity. The concave portion can have a closed loop shape along the circumferential direction of the lower surface of the cavity. At this time, the concave portion may include a portion having a step in one embodiment, and may not have a step in another embodiment.

Therefore, the embodiment arranges a connection member and a molding member for molding the connection member in the cavity. In addition, the molding member can fill the concave portion provided in the cavity. At this time, the embodiment may allow a portion of an entire region of the molding member positioned in the concave portion to function as an anchor. Therefore, the embodiment can improve the adhesion between the circuit board and the molding member. Accordingly, the embodiment can protect the connection member more stably. In addition, the embodiment can further improve product reliability of the semiconductor package.

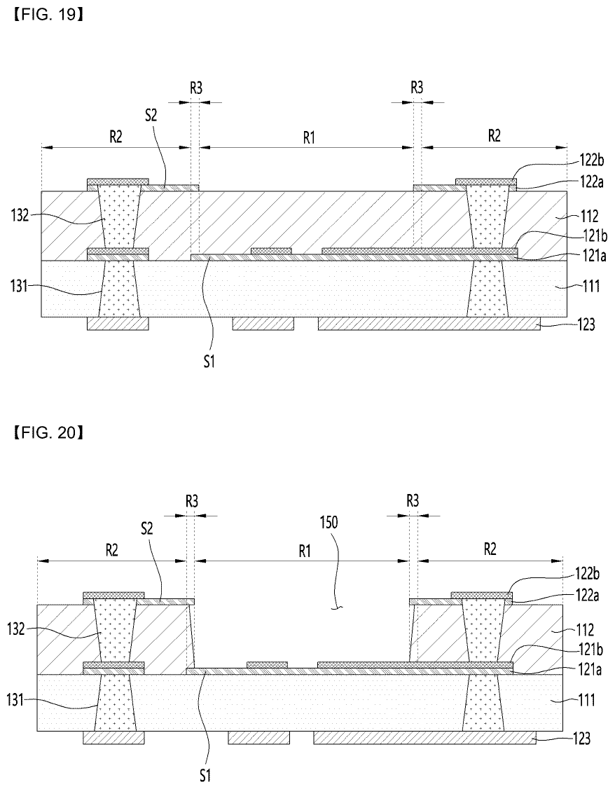

FIG. 11 is a drawing showing a package substrate according to an embodiment.

Referring to FIG. 11, the package substrate may include a contacting member 310 disposed on the first pad 121-1, and a connection member 320 disposed on the contacting member 310.

The connection member may be any one of a second circuit board, a semiconductor device, and a connection substrate described in FIGS. 1a to 1g.

Meanwhile, a molding member 330 may be disposed in the cavity 150. The molding member 330 may be disposed by molding the connection member 320 in the cavity 150.

At this time, at least a portion of the molding member 330 may be disposed to fill the first concave portion 150-3 and the second concave portion 150-4 provided in the cavity 150. The portions of the molding member 330 disposed in the first concave portion 150-3 and the second concave portion 150-4 can function as anchors. Accordingly, the embodiment can further improve the adhesion between the molding member 330 and the circuit board.

Hereinafter, a method for manufacturing a circuit board of the embodiment will be described.

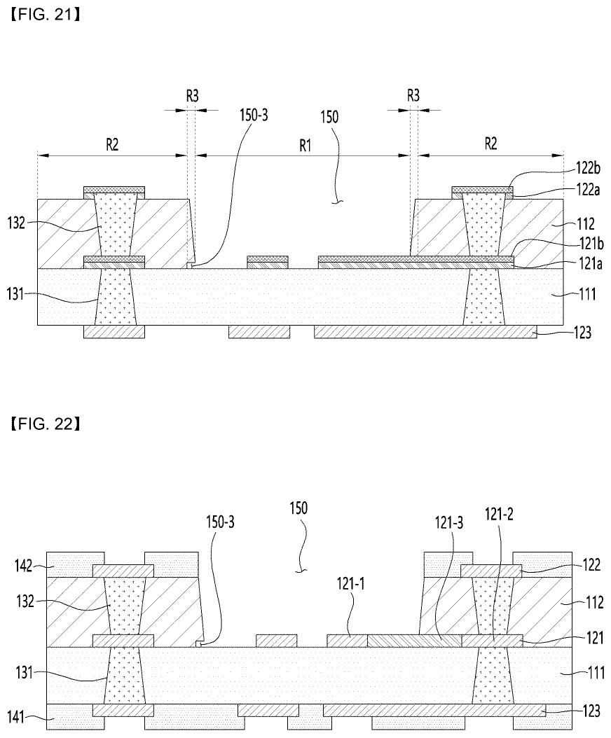

FIGS. 12 to 22 are drawings showing a manufacturing method of the circuit board of FIG. 2 according to the embodiment in order of processes.

Referring to FIG. 12, the embodiment prepares an insulating member that is a basis for manufacturing a circuit board.

For example, the embodiment prepares an insulating member including a first insulating layer 111 and a metal layer on the first insulating layer 111.

The metal layer may include a metal layer 121a disposed on the first insulating layer 111 and a metal layer 123a disposed under the first insulating layer 111. In addition, the metal layer 121a can be used as a seed layer for forming the first circuit pattern layer 121 by electrolytic plating. In addition, the metal layer 123a can be used as a seed layer for forming the third circuit pattern layer 123 by electrolytic plating.

Next, referring to FIG. 13, the embodiment performs electrolytic plating on the metal layers 121a and 123a as seed layers to form the second metal layer 121b of the first circuit pattern layer 121, the second metal layer 123b of the third circuit pattern layer 123, and the first through electrode 131 passing through the first insulating layer 111.

At this time, a substrate manufactured up to a process of FIG. 13 can include a first region R1, a second region R2, and a third region R3. The first region R1 may be a region corresponding to a size of an actual cavity 150. In addition, the second region R2 may be a region where the cavity 150 is not formed. In addition, the third region R3 refers to a boundary region between the first region R1 and the second region R2. The third region R3 may be a region that takes into account a process error in a process of forming the cavity.

Thereafter, referring to FIG. 14, the embodiment arranges a dry film DF1 on the first region R1 and the third region R3 of the first circuit pattern layer 121. The dry film DF1 may prevent the first metal layer 121a to be used as a stopper in a first etching process from being removed.

Next, referring to FIG. 15, the embodiment can perform a process of removing the first metal layer 121a of the first circuit pattern layer 121 and the first metal layer 123a of the third circuit pattern layer 123 in a region where the dry film DF1 is not disposed. Through this, the embodiment can form the second pad 121-2 of the first circuit pattern layer 121 and the third circuit pattern layer 123.

That is, referring to FIG. 16, all of the portions of the first metal layer 121a disposed in the second region R1 that do not vertically overlap with the second metal layer 121b can be removed. Accordingly, the second pad 121-2 and a part of the electrode pattern 221-3 (for example, a second portion 121-32) of the first circuit pattern layer 121 can be formed. At this time, the first metal layer 121a disposed in the first region R1 and the third region R3 can be used as a first stopper S1 in the process of forming the cavity 150.

Next, referring to FIG. 17, the embodiment can arrange a second insulating layer 112 on the first insulating layer 111. At this time, the first metal layer 122a of the second circuit pattern layer 122, which is a seed layer of the second circuit pattern layer 122, can be disposed on an upper surface of the second insulating layer 112.

Next, referring to FIG. 18, the embodiment can proceed with a process of forming a second metal layer 122b of the second circuit pattern layer 122 by performing electrolytic plating using the first metal layer 122a of the second circuit pattern layer 122 as a seed layer. At this time, the second through electrode 132 passing through the second insulating layer 112 may be formed together with the second metal layer 122b.

Next, referring to FIG. 19, the embodiment may perform a process of removing the first metal layer 122a of the second circuit pattern layer 122 by etching. At this time, the embodiment may not completely remove the first metal layer 122a of the second circuit pattern layer 122 but may leave some of the first metal layer 122a of the second circuit pattern layer 122. For example, the embodiment may completely remove a portion of the first metal layer 122a of the second circuit pattern layer 122 disposed in the first region R1. In addition, the embodiment does not remove a part of the first metal layer 122a of the second circuit pattern layer 122 in the third region R3 and the second region R2 adjacent to the third region R3. This can be used as a second stopper S2 in the process of forming the cavity 150. In this case, the first stopper S1 and the second stopper S2 may include portions vertically overlapping each other. For example, the first stopper S1 and the second stopper S2 can vertically overlap in the third region R3. Through this, the embodiment can prevent a size of the cavity 150 from expanding in a process of forming the cavity 150.

Next, referring to FIG. 20, the embodiment can form a cavity 150 passing through the second insulating layer 112 by using the first stopper S1 and the second stopper S2.

In this case, the cavity 150 may not vertically overlap the third region R3 at a lower end of the side wall 150-2 of the cavity 150.

Thereafter, referring to FIG. 21, the embodiment may perform a process of removing the first stopper S1 and the second stopper S2 by etching In this case, the second stopper S2 may be easily removed because an insulating layer covering the second stopper S2 does not exist thereon.

In contrast, a portion corresponding to the third region R3 among the entire region of the first stopper S1 is covered with the second insulating layer 112. At this time, if etching is performed on a portion corresponding to the first region R1 among the entire region of the first stopper S1, overetching may be performed. In addition, the embodiment can easily remove the first stopper S1 in the third region R3 by utilizing the overetching. Accordingly, a first concave portion 150-3, which is a position where the first stopper S1 is removed, can be provided at a lower end of the side wall 150-2 of the cavity 150.

Next, referring to FIG. 22, the embodiment can perform a process of forming a first protective layer 141 under the first insulating layer 111 and forming a second protective layer 142 on the second insulating layer 112.

On the other hand, when the circuit board having the above-described characteristics of the invention is used in an IT device or home appliance such as a smart phone, a server computer, a TV, and the like, functions such as signal transmission or power supply can be stably performed. For example, when a circuit board having the features of the present invention performs a semiconductor package function, the circuit board can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A circuit board comprising:
a first insulating layer;
a second insulating layer disposed on the first insulating layer; and
a circuit pattern layer disposed between the first and second insulating layers,
wherein the second insulating layer has a cavity passing through upper and lower surfaces, and
wherein the circuit pattern layer includes an electrode pattern extending from an inner side of the cavity to an outer side of the cavity.

2. The circuit board of claim 1, wherein the circuit pattern layer further includes:
a first pad disposed on the inner side of the cavity overlapped in a vertical direction with the cavity; and
a second pad disposed on the outer side of the cavity that does not vertically overlap with the cavity.

3. The circuit board of claim 2, wherein the electrode pattern directly connects between the first pad and the second pad.

4. The circuit board of claim 1, wherein the second insulating layer has a concave portion recessed in a direction from a lower end of a sidewall of the cavity toward the outer side of the cavity.

5. The circuit board of claim 4, wherein the concave portion has a first portion that does not overlap with the electrode pattern in a vertical direction, and a second portion that overlaps with the electrode pattern in the vertical direction.

6. The circuit board of claim 3, wherein the circuit pattern layer is provided to protrude on the first insulating layer, and wherein the first portion of the concave portion is provided along an edge of the lower end of the side wall of the cavity.

7. The circuit board of claim 5, wherein the first and second portions of the concave portion have a step.

8. The circuit board of claim 5, wherein each of the first pad, the second pad, and the electrode pattern includes:
a first metal layer disposed on the first insulating layer; and
a second metal layer disposed on the first metal layer, and
wherein a length of the first portion of the concave portion in the vertical direction corresponds to a thickness of the first metal layer.

9. The circuit board of claim 5, wherein a horizontal distance from the lower end of the side wall of the cavity to an innermost end of the first portion of the concave portion satisfies a range of 5 μm to 17 μm.

10. The circuit board of claim 5, wherein a horizontal length of the first portion of the concave portion is different from a horizontal length of the second portion of the concave portion.

11. The circuit board of claim 2, wherein a thickness of the first pad is different from a thickness of the second pad.

12. The circuit board of claim 11, wherein the thickness of the first pad is smaller than the thickness of the second pad.

13. The circuit board of claim 8, wherein the length of the first portion of the concave portion in the vertical direction satisfies a range of 1.0 μm to 4.0 μm.

14. The circuit board of claim 10, wherein the horizontal length of the first portion of the concave portion is smaller than the horizontal length of the second portion of the concave portion.

15. The circuit board of claim 10, wherein the electrode pattern includes a protrusion protruding toward an upper surface of the second insulating layer.

16. The circuit board of claim 15, wherein the protrusion overlaps the side wall of the cavity in the vertical direction.

17. The circuit board of claim 2, wherein the first pad, the second pad, and the electrode pattern are embedded in the upper surface of the first insulating layer, and
wherein the cavity includes a through hole passing the upper surface and the lower surface of the second insulating layer, and a recess connected to the through hole and concavely provided at an upper surface of the first insulating layer.

18. The circuit board of claim 17, wherein the upper surface of the first insulating layer has a step.

19. The circuit board of claim 17, wherein an upper surface of the electrode pattern has a step.

20. The circuit board of claim 17, wherein the first insulating layer and the second insulating layer include different insulating materials.
